(19) United States
(12) Patent Application Publication
(10) Pub. No.: US 2025/0376369 A1
(43) Pub. Date: Dec. 11, 2025

(54) DEVICES, SYSTEMS, AND METHODS INCLUDING MICRO- OR NANO- CANTILEVER STRUCTURES

(71) Applicants: The MITRE Corporation, McLean, VA (US); Massachusetts Institute of Technology, Cambridge, MA (US)

(72) Inventors: Henry WEN, Reading, MA (US); Matthew ZIMMERMANN, McLean, VA (US); Andrew GREENSPON, McLean, VA (US); Matthew SAHA, McLean, VA (US); Dirk ENGLUND, Brookline, MA (US)

(73) Assignees: The MITRE Corporation, McLean, VA (US); Massachusetts Institute of Technology, Cambridge, MA (US)

(21) Appl. No.: 19/094,314

(22) Filed: Mar. 28, 2025

Related U.S. Application Data
(60) Provisional application No. 63/657,660, filed on Jun. 7, 2024.

(51) Int. Cl. B81B 3/00; G02B 6/35

(52) U.S. Cl. CPC B81B 3/0043; G02B 6/3504; G02B 6/3578; G02B 6/359; B81B 2201/045; B81B 2203/0118; B81B 2203/0307; B81B 2203/0338; B81B 2203/04

(57) ABSTRACT

A cantilever that includes a first dielectric layer with a first intrinsic stress, a second dielectric layer overlaying the first dielectric layer, in which the second dielectric layer has a second intrinsic stress that is different than the first intrinsic stress, the cantilever including a first piezoelectric segment disposed between the first dielectric layer and the second dielectric layer at a first position with respect to a first dimension parallel to the first dielectric layer, the cantilever including a second piezoelectric segment disposed between the first dielectric layer and the second dielectric layer at a second position with respect to the first dimension, and the cantilever including one or more waveguides patterned in the second dielectric layer.

### CROSS-REFERENCE TO RELATED APPLICATIONS

This application claims the benefit of U.S. Provisional Application No. 63/657,660, filed Jun. 7, 2024, the entire contents of each of which is incorporated herein by reference.

### FIELD

The present disclosure relates generally to micro-mechanical and nano-mechanical cantilevers for use in microelectromechanical systems (MEMS), photonic devices, micro-robotic devices, and the like.

### BACKGROUND

The scalability of a micron-scale or nano-scale system is often restricted by an inability to effectively interconnect system components without compromising important system characteristics (e.g., size or efficiency). For example, the scalability of a photonic integrated circuit may be limited by an inability to perform crucial functions such as the steerable projection and collection of optical modes between the circuit and a set of targets in free space without using devices that have relatively large footprints (e.g., MEMs mirrors) or devices that are challenging to integrate (e.g., optical phase arrays). These challenges can hamper the development of technologies that can be formed from networks of micron-scale and nano-scale devices.

### SUMMARY

Described are micron-scale and nano-scale curving or curling cantilever structures for use in a wide range of applications, including as components of photonic and electronic integrated circuits. The provided cantilevers can be fabricated using wafer-scale fabrication techniques and materials (e.g., CMOS fabrication techniques and materials) and can comprise a stack of dielectric layers having differing intrinsic stress values. When a cantilever is released from its underlying substrate during fabrication, the non-zero stress gradient across its constituent dielectric layers causes the cantilever to deflect and curve along its length.

The topmost dielectric layer (relative to the substrate to which the cantilever is anchored) of a cantilever can be geometrically configured to amplify the cantilever's deflection along its length. Etching the topmost dielectric layer into a plurality of lateral crossbars, for example, can redirect lateral stress (e.g., stress along the width of the cantilever) in the cantilever along the cantilever's length to increase the longitudinal deflection of the cantilever. Varying properties of the crossbar pattern such as the crossbar duty cycle can program the curvature of the cantilever and, in some embodiments, can enable to cantilever to assume complex geometric structures once released from the underlying substrate.

The curving of a cantilever can be passive or can be actively controlled. A passive curving cantilever may permanently assume a curved shape after being released from the underlying substrate. Actively controlled curving cantilevers, on the other hand, can be moved as needed between two or more curvature states, e.g., via piezoelectric actuation. For example, an active curving cantilever may be configured to be moved between an undeflected state and a deflected state.

The provided cantilevers can be implemented as optical interconnects in optical systems such as photonic integrated circuits (PICs) by patterning a waveguide channel within the topmost cantilever layer and can enable crucial functionalities such as the steerable projection and collection of multiple optical modes between a PIC and a set of targets in free space. Active curving cantilevers (e.g., piezoelectrically actuated cantilevers) in particular can enable, e.g., two-dimensional beam scanning from anywhere on a photonic chip over a large number of diffraction limited spots in the far field. Advantageously, unlike beam scanning approaches that rely on reflective scanners, integrated optical phase arrays, or scanning fibers, the disclosed cantilevers are highly scalable and have small footprints (e.g., less than 1 mm²), wide fields-of-view, and broadband outputs. As a result, the provided cantilevers can facilitate the creation of complex optical systems such as quantum computers.

Example applications of the cantilevers to several technical fields are also described. In particular, applications of the cantilevers to photonic circuits such as qubit control systems are provided.

According to some embodiments, a cantilever is provided that comprises a first dielectric layer, wherein the first dielectric layer has a first intrinsic stress, a second dielectric layer overlaying the first dielectric layer, wherein the second dielectric layer has a second intrinsic stress that is different than the first intrinsic stress, a first piezoelectric segment disposed between the first dielectric layer and the second dielectric layer at a first position with respect to a first dimension parallel to the first dielectric layer, a second piezoelectric segment disposed between the first dielectric layer and the second dielectric layer at a second position with respect to the first dimension, and one or more waveguides patterned in the second dielectric layer.

In any of these embodiments, the second dielectric layer comprises a plurality of crossbars oriented at an angle relative to a length of the cantilever to control curvature in a width-wise x-dimension of the cantilever perpendicular to the direction of propagation of light in the one or more waveguides. In any of these embodiments, the patterning of the plurality of crossbars is periodic. In any of these embodiments, a period of the patterning of the plurality of crossbars is greater than or equal to 0.5 microns. In any of these embodiments, the cantilever is fabricated with a removable sacrificial layer that binds the cantilever to a substrate, wherein, when the sacrificial layer is removed, the cantilever deflects along the longitudinal dimension of the cantilever relative to the substrate. In any of these embodiments, the cantilever deflects in a direction away from the substrate. In any of these embodiments, the cantilever deflects in a direction toward the substrate. In any of these embodiments, the deflection of the cantilever relative to the substrate increases from a first end along the length of the cantilever.

In any of these embodiments, the first dimension is a width-wise x-dimension of the cantilever perpendicular to the direction of propagation of light in the one or more waveguides. In any of these embodiments, the first piezoelectric segment is disposed adjacent in the x-dimension to a first side of a waveguide of the one or more waveguides patterned in the second dielectric layer. In any of these embodiments, the second piezoelectric segment is disposed adjacent in the x-dimension to a second side, opposite the first side, of the waveguide.

In any of these embodiments, the cantilever comprising a third piezoelectric segment disposed between the first dielectric layer and the second dielectric layer, wherein the first piezoelectric segment is disposed at a first position with respect to a x-dimensional dimension of the cantilever, and wherein the third piezoelectric segment is disposed at a second position with respect to the x-dimensional dimension of the cantilever. In any of these embodiments, the first piezoelectric segment is disposed at a first position with respect to a x-dimensional dimension of the cantilever, and the second piezoelectric segment is disposed at a second position with respect to the x-dimensional dimension of the cantilever. In any of these embodiments, the first dimension is a x-dimensional dimension of the cantilever.

According to some embodiments, a system is provided that comprises the cantilever of some embodiments described above, a light source configured to direct light into a waveguide of the one or more waveguides of the cantilever, and one or more voltage sources configured to apply a first voltage to the first piezoelectric segment and a second voltage to the second piezoelectric segment.

In any of these embodiments, the system comprising one or more processors configured to control the one or more voltage sources to cause deflection of the cantilever tip in an x-dimension and a y-dimension, wherein the x-dimension is width-wise dimension of the cantilever, the y-dimension is a thickness dimension of the cantilever, and the x-dimension and the y-dimension are perpendicular to one another and are both perpendicular to a positive z direction defined by the direction of propagation of light in the one or more waveguides. In any of these embodiments, the one or more processors are configured to control the one or more voltage sources to apply the first voltage to drive the first piezoelectric segment at a first frequency and the second voltage to drive the second piezoelectric segment at the first frequency to induce oscillation of the cantilever at a x-dimensional resonance frequency.

In any of these embodiments, the one or more processors are configured to control the one or more voltage sources to modulate an amplitude of the first and/or second voltage in accordance with a y-dimensional cancellation amplitude of the cantilever. In any of these embodiments, the one or more processors are configured to control the one or more voltage sources to modulate a relative phase of the first and second voltages with respect to one another in accordance with a y-dimensional cancellation phase of the cantilever. In any of these embodiments, the one or more processors are configured to control the one or more voltage sources to detect a position of output light output from the waveguide in an imaging plane over time as the cantilever is driven at the x-dimensional resonance frequency and modulate the first and/or second voltage in accordance with the monitored position of the output light in the imaging plane.

In any of these embodiments, the one or more processors are configured to control the one or more voltage sources to apply the first voltage to drive the first piezoelectric segment at the first frequency and the second voltage to drive the second piezoelectric segment at the first frequency to induce oscillation of the cantilever at a y-dimensional resonance frequency. In any of these embodiments, the one or more processors are configured to control the one or more voltage sources to modulate the amplitude of the first and/or second voltage in accordance with a x-dimensional cancellation amplitude of the cantilever. In any of these embodiments, the one or more processors are configured to control the one or more voltage sources to modulate the relative phase of the first and second voltages with respect to one another in accordance with a x-dimensional cancellation phase of the cantilever.

In any of these embodiments, the one or more processors are configured to control the one or more voltage sources to detect a position of output light output from the waveguide in an imaging plane over time as the cantilever is driven at the y-dimensional resonance frequency and modulate the first and/or second voltage in accordance with the monitored position of the output light in the imaging plane.

In any of these embodiments, the one or more processors are configured to control the one or more voltage sources to apply the first voltage to drive the first piezoelectric segment and the second voltage to drive the second piezoelectric segment to induce oscillation of the cantilever in accordance with a Lissajous pattern, wherein the Lissajous pattern is generated in accordance with a ratio of the y-dimensional resonance frequency of the cantilever and the x-dimensional resonance frequency of the cantilever. In any of these embodiments, the one or more processors are configured to control the light source to apply pulsed light to the waveguide as the cantilever oscillates in accordance with the Lissajous pattern.

Any one or more features from any of the above embodiments may be combined, in whole or in part, with all or part of any of the other embodiments and/or with all or part of any other disclosure herein.

### BRIEF DESCRIPTION OF THE FIGURES

The invention will now be described, by way of example only, with reference to the accompanying drawings. The patent or application file contains at least one drawing executed in color. Copies of this patent or patent application publication with color drawings will be provided by the office upon request and payment of the necessary fee.

FIG. 1 shows a head-on, cross-sectional view of a cantilever, according to some embodiments.

FIG. 2A shows a top-down view of a cantilever, according to some embodiments.

FIG. 2B shows a perspective view of a redirection layer of a cantilever, according to some embodiments.

FIG. 3A shows lateral deformation in a cantilever without a crossbar-patterned redirection layer, according to some embodiments.

FIG. 3B shows lateral deformation in a cantilever with a crossbar-patterned redirection layer, according to some embodiments.

FIG. 4A shows a side view of a cantilever prior to release, according to some embodiments.

FIG. 4B shows a side view of a cantilever immediately following release, according to some embodiments.

FIG. 4C shows a side view of a deflected cantilever, according to some embodiments.

FIG. 5A provides example data showing relationships between cantilever deflection, crossbar period, and crossbar width.

FIG. 5B provides example data characterizing the deflected state of a cantilever configured to have a constant radius of curvature.

FIG. 6A shows a head-on, cross-sectional view of a cantilever patterned with a waveguide, according to some embodiments.

FIG. 6B shows a perspective view of a redirection layer in a cantilever patterned with a waveguide, according to some embodiments.

FIG. 7 shows a side view of a deflected, waveguide-patterned cantilever, according to some embodiments.

FIG. 8 shows a head-on, cross-sectional view of a piezoelectrically-actuated cantilever, according to some embodiments.

FIG. 9A shows a side view of a piezoelectrically-actuated cantilever with no voltage applied across the piezoelectric layer, according to some embodiments.

FIG. 9B shows a side view of a piezoelectrically-actuated cantilever with a voltage applied across the piezoelectric layer, according to some embodiments.

FIG. 10 shows a head-on, cross-sectional view of a piezoelectrically-actuated cantilever that is patterned with a waveguide, according to some embodiments.

FIG. 11 shows an example of a crossbar pattern for creating helical structures.

FIG. 12 shows an example of a ball-shaped structure.

FIG. 13 shows an example of a toroidal structure.

FIG. 14A shows a gripping actuator for a micro-robotic system, according to some embodiments.

FIG. 14B shows a gripping actuator for a micro-robotic system, according to some embodiments.

FIG. 14C shows a gripping actuator for a micro-robotic system, according to some embodiments.

FIG. 15 shows a sideways-twisting cantilever, according to some embodiments.

FIG. 16A shows a “candy-cane” photonic coupler, according to some embodiments.

FIG. 16B shows a “candy-cane” photonic coupler directing waveguide output toward a reflective substrate, according to some embodiments.

FIG. 17A shows a “stair-step” photonic coupler, according to some embodiments.

FIG. 17B shows waveguide output from a “stair-step” photonic coupler, according to some embodiments.

FIG. 18 shows an angle-boosted cantilever, according to some embodiments.

FIG. 19A-B show twisted, piezoelectrically-controlled cantilevers, according to some embodiments.

FIG. 20 shows ball-lens terminated cantilevers, according to some embodiments.

FIG. 21 shows a periodic optical switch that is implement using a piezoelectrically-actuated cantilever patterned with a waveguide, according to some embodiments.

FIG. 22 shows a photonic cantilever with low output divergence, according to some embodiments.

FIG. 23A shows a system for high-speed optical pulsing for qubit control, according to some embodiments.

FIG. 23B shows a system for high-speed optical pulsing for qubit control, according to some embodiments.

FIG. 24 shows a system for controlling qubit color centers relative to photonic integrated circuit (PIC) edge excitation and collection or top-down confocal excitation and collection, according to some embodiments.

FIG. 25A shows a cantilever with two independent directionally controlled segments, according to some embodiments.

FIG. 25B shows a cantilever with two independent directionally controlled segments, according to some embodiments.

FIG. 26 shows a block diagram of a system for actuating a cantilever that is patterned with a waveguide, according to some embodiments.

FIG. 27 shows a top-down view of a cantilever comprising split actuators, according to some embodiments.

FIG. 28A shows a method for determining y-dimensional and x-dimensional cancellation phases and cancellation amplitudes, according to some embodiments.

FIG. 28B shows example waveguide output images that can be observed while determining the y-dimensional cancellation phase and y-dimensional cancellation amplitude.

FIG. 28C show example waveguide output images that can be observed while determining the x-dimensional cancellation phase and x-dimensional cancellation amplitude.

FIG. 29A shows a method for determining global y-dimensional and x-dimensional phase offsets, according to some embodiments.

FIG. 29B shows example horizontal, vertical, and crosshair alignment patterns.

FIG. 29C shows example waveguide output images that can be observed while determining the global y-dimensional phase offset.

FIG. 29D shows example waveguide output images that can be observed while determining the global x-dimensional phase offset.

FIG. 29E shows example waveguide output images that can be observed while determining global y-dimensional and x-dimensional phase offsets.

FIG. 30A shows a method for high-rate, low-fill projection, according to some embodiments.

FIG. 30B shows an example movement pattern of a cantilever tip and a corresponding pulsed output from the cantilever waveguide, according to some embodiments.

FIG. 31 shows a top-down view of a cantilever comprising split actuators, according to some embodiments.

FIG. 32A shows an example cantilever device curling upward, with cross sections showing the TE single mode profile along the waveguide for 737 nm light, according to some embodiments.

FIG. 32B shows example output from a cantilever magnified onto an ICCD camera, according to some embodiments.

FIG. 32C shows a camera image of example cantilevers on PICs, according to some embodiments.

FIG. 32D shows example data comparing the scan speed of different types of 2D laser beam scanners, according to some embodiments.

FIG. 32E shows an example PIC with multiple cantilever devices, according to some embodiments.

FIG. 33A shows an example cantilever without crossbar patterning and an example cantilever with crossbar patterning, along with example data comparing the curling behavior of the two, according to some embodiments.

FIGS. 33B-33D shows the curling behavior of example cantilevers of varying widths, waveguide numbers, and crossbar duty cycles, according to some embodiments.

FIG. 33E shows vertical displacement measurements along the length of an example cantilever, according to some embodiments.

FIG. 33F shows data relating the out of plane position, longitudinal position, and radius of curvature of an example cantilever at different DC voltages, according to some embodiments.

FIG. 34A show finite element simulations of the first six resonant modes of an example cantilever, according to some embodiments.

FIG. 34B show example ICCD measurements of an imaged cantilever beam tip at different resonant modes with varying drive voltages, according to some embodiments.

FIG. 34C shows frequency response data and ringdown measurement data for an example cantilever at varying pressures, according to some embodiments.

FIG. 35A shows a top-down SEM image of an example split-actuator cantilever, according to some embodiments.

FIG. 35B shows example frequency response data from position sensitive detector measurements of beam displacement with respect to applied voltage, according to some embodiments.

FIG. 35C shows example ICCD capture of a cantilever waveguide tip tracing high-rate Lissajous curves, according to some embodiments.

FIG. 35D shows a computer render of an example cantilever being driven in two dimensions with an optical pulse sequence in order to project arbitrary images, according to some embodiments.

FIG. 35E shows example images generated using a high-fill Lissajous pattern, according to some embodiments.

FIG. 35F shows example high-fill beam streak images captured on an ICCD with varying vertical and horizontal amplitudes, according to some embodiments.

FIG. 36A shows an example diamond quantum microchiplet overhanging a cleaved silicon chip, according to some embodiments.

FIG. 36B shows an example second order autocorrelation measurement of a single emitter in a diamond waveguide that was excited using output from a cantilever device, according to some embodiments.

FIG. 36C shows example time-dependent fluorescence of a single emitter when driving a cantilever at 3170 Hz with 100 Vpp, according to some embodiments.

FIG. 36D shows example ensemble fluorescence measurements collected using a ICCD, according to some embodiments.

FIG. 36E shows an example experimental setup for cantilever control of diamond chiplet emitters, according to some embodiments.

FIGS. 37A-37D shows a technique for using a frequency-multiplexed input and ring resonators to address multiple color centers on a diamond waveguide array, according to some embodiments.

### DETAILED DESCRIPTION

Described are micron-scale and nano-scale curving or curling cantilever structures and devices and systems including such structures for use in a wide range of applications. For example, described are cantilever structures that can be used as components of photonic and electronic integrated circuits. The provided cantilevers can be fabricated using wafer-scale fabrication techniques and materials (e.g., conventional CMOS fabrication techniques and materials). An exemplary cantilever can comprise a stack of dielectric layers having differing intrinsic stress values. When the cantilever is released from its underlying substrate during fabrication, the non-zero stress gradient across its constituent dielectric layers causes the cantilever to deflect and curve along its length.

The topmost dielectric layer (relative to the substrate to which the cantilever is anchored) of a cantilever can be geometrically configured to amplify the cantilever's deflection along its length. Etching the topmost dielectric layer into a plurality of lateral crossbars, for example, can redirect lateral stress (e.g., stress along the width of the cantilever) in the cantilever along the cantilever's length to increase the longitudinal deflection of the cantilever. Varying properties of the crossbar pattern such as the crossbar duty cycle can program the curvature of the cantilever and, in some embodiments, can enable to cantilever to assume complex geometric structures once released from the underlying substrate.

The curving of a cantilever can be passive or can be actively controlled. A passive curving cantilever may permanently assume a curved shape after being released from the underlying substrate. Actively controlled curving cantilevers, on the other hand, can be moved as needed between two or more curvature states, e.g., via piezoelectric actuation. For example, an active curving cantilever may be configured to be moved between an undeflected state and a deflected state.

The provided cantilevers can be implemented as optical interconnects in optical systems such as photonic integrated circuits (PICs) by patterning a waveguide channel within the topmost cantilever layer and can enable crucial functionalities such as the steerable projection and collection of multiple optical modes between a PIC and a set of targets in free space. Active curving cantilevers (e.g., piezoelectrically actuated cantilevers) in particular can enable, e.g., two-dimensional beam scanning from anywhere on a photonic chip over a large number of diffraction limited spots in the far field. Advantageously, unlike beam scanning approaches that rely on reflective scanners, integrated optical phase arrays, or scanning fibers, the disclosed cantilevers are highly scalable and have small footprints (e.g., less than 1 mm²), wide fields-of-view, and broadband outputs. As a result, the provided cantilevers can facilitate the creation of complex optical systems such as quantum computers.

According to various embodiments, cantilevers configured according to the principles described herein are used in micro- and nano-electromechanical systems (MEMs and NEMs), micro- and nano-scale robotics, and self-assembling micro- and nano-scale structures.

While this disclosure describes the positive z-direction as the direction in which light travels in the waveguide along the length of the cantilever, a person of skill in the art will appreciate that sign convention for the direction of light propagation is arbitrary. For instance, the sign of the z-direction and the related orientation (e.g., “handedness”) of the Cartesian convention does not affect x-directional and y-directional displacement equations, voltage equations, etc. described herein.

Any of the systems, methods, techniques, and/or features disclosed herein may be combined, in whole or in part, with any other disclosed systems, methods, techniques, and/or features. As used herein, the singular forms “a”, “an”, and “the” include the plural reference unless the context clearly dictates otherwise. Reference to “about” a value or parameter or “approximately” a value or parameter herein includes (and describes) variations that are directed to that value or parameter per se. For example, description referring to “about X” includes description of “X”. It is understood that aspects and variations of the invention described herein include “consisting of” and/or “consisting essentially of” aspects and variations. When a range of values or values is provided, it is to be understood that each intervening value between the upper and lower limit of that range, and any other stated or intervening value in that stated range, is encompassed within the scope of the present disclosure. Where the stated range includes upper or lower limits, ranges excluding either of those included limits are also included in the present disclosure.

### Passive Curving Cantilevers

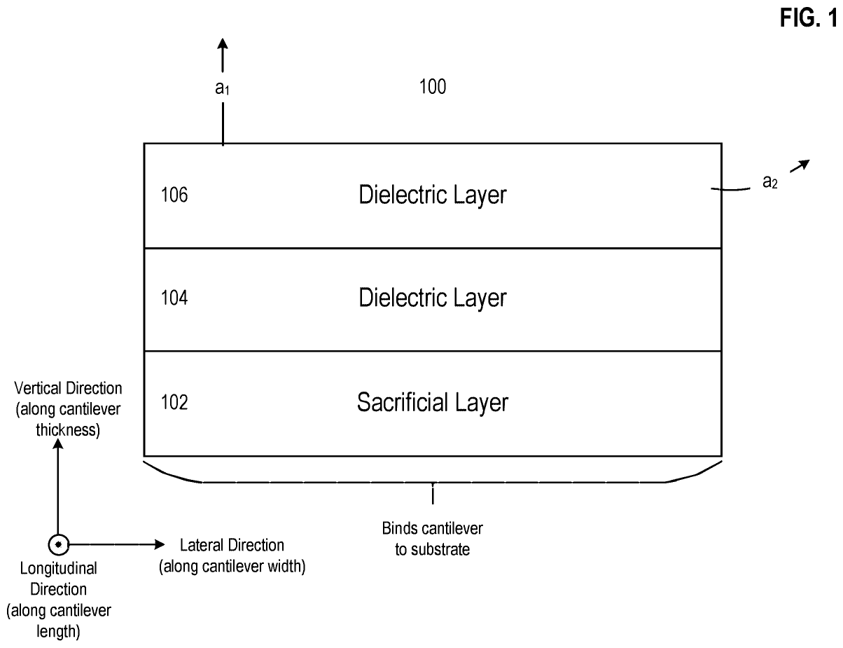

A head-on, cross-sectional view of an exemplary cantilever 100 is provided in FIG. 1. Cantilever 100 may be beam-shaped, i.e., may be longer in a first dimension (the longitudinal direction in FIG. 1) than in a second dimension (the lateral x-dimensional direction in FIG. 1) or a third dimension (the vertical direction in FIG. 1). Reference herein to the length of cantilever 100 (e.g., description of cantilever 100 deflecting or deforming “along its length”) may be interpreted as reference to the longest, longitudinal dimension of cantilever 100, and may be referred to as a z-dimension of the cantilever. Reference to the width of cantilever 100 (e.g., description of cantilever 100 deflecting or deforming “along its width”) may be interpreted as reference to the shorter, x-dimensional dimension of cantilever 100 that is co-planar with the longitudinal dimension of cantilever 100, and may be referred to as an x-dimension of the cantilever. The thickness of the cantilever may be the third Cartesian dimension, referred to as a y-dimension of the cantilever and perpendicular to both the x-dimension and z-dimension.

As shown, cantilever 100 may include several layers: a sacrificial (i.e., release) layer 102, a first, bottom dielectric layer 104, and a second, top dielectric layer 106. Sacrificial layer 102 may bind cantilever 100 to a substrate (e.g., a substrate of an integrated circuit chip) and may be any material layer deposited in the layer stack of cantilever 100 that can be preferentially removed or etched away, e.g., by a wet chemical etch or a gaseous chemical etch, compared to the other materials that constitute cantilever 100 in order to release the overlying layers of cantilever 100 (layers 104-106) from the substrate. For example, sacrificial layer 102 may be a layer of amorphous silicon that can be etched away using a xenon difluoride gas that does not etch the overlying cantilever layers (layers 104-106). An amorphous silicon sacrificial layer can also be removed using various concentrations of potassium hydroxide. If the overlying dielectric layers 104 and 106 do not comprise silicon dioxide, then sacrificial layer 102 can be silicon dioxide or another oxide glass and may be removed using a wet etch of hydrofluoric acid.

Dielectric layers 104 and 106 may be any thin film dielectrics having intrinsic stresses (e.g., silicon dioxide or silicon nitride). The intrinsic stress of layer 106 may be different (e.g., more compressive or more tensile) than the intrinsic stress of layer 104; this difference may be the result of material or chemical differences between layer 104 and layer 106 or, if layer 104 and layer 106 have the same chemical composition, the result of differences in the conditions under which each layer was deposited during the fabrication of cantilever 100. For example, if both layer 104 and layer 106 comprise silicon dioxide or silicon nitride, layer 104 may be configured to have a different intrinsic stress than layer 106 by depositing layer 104 at a different flow rate than the flow rate used to deposit layer 106. Other deposition conditions that may be varied in order to configure the stresses of layers 104 and 106 include the mixture of precursor gases used during deposition, plasma pressure, plasma frequency, and power in a chemical vapor deposition chamber. Post-deposition annealing can also change the intrinsic stress of an as-deposited film.

When sacrificial layer 102 is removed and cantilever 100 is released from the substrate, the gradient of intrinsic stress between layer 104 and layer 106 may cause cantilever 100 to deflect along its length (e.g., longitudinally deflect) relative to the substrate (e.g., as indicated by arrow a₁). In order to concentrate the deflection caused by the gradient of intrinsic stress between layer 104 and layer 106 in the longitudinal direction and to reduce lateral strain in cantilever 100 that can cause cantilever 100 to curl along its width (as indicated by arrow a₂), layer 106 can be geometrically patterned atop layer 104 such that lateral strain is redirected in the longitudinal direction—i.e., along the length of cantilever 100—to increase the amount by which cantilever 100 deflects along its length.

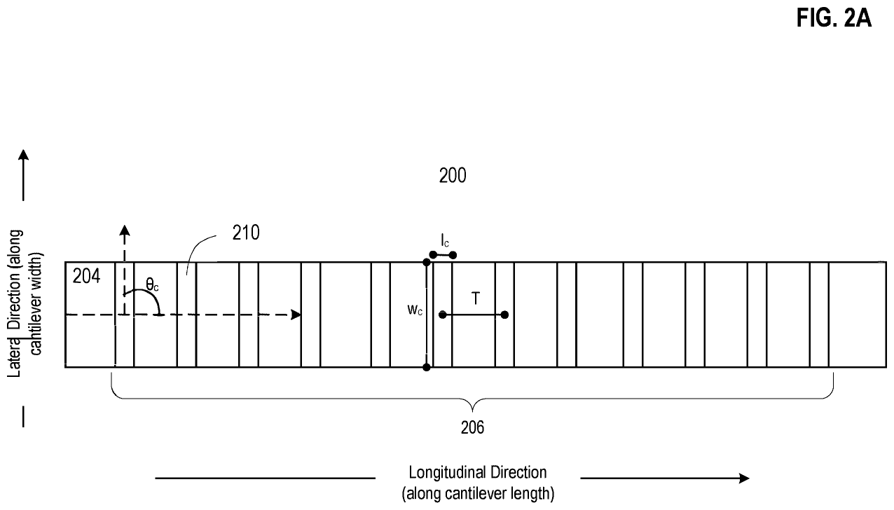

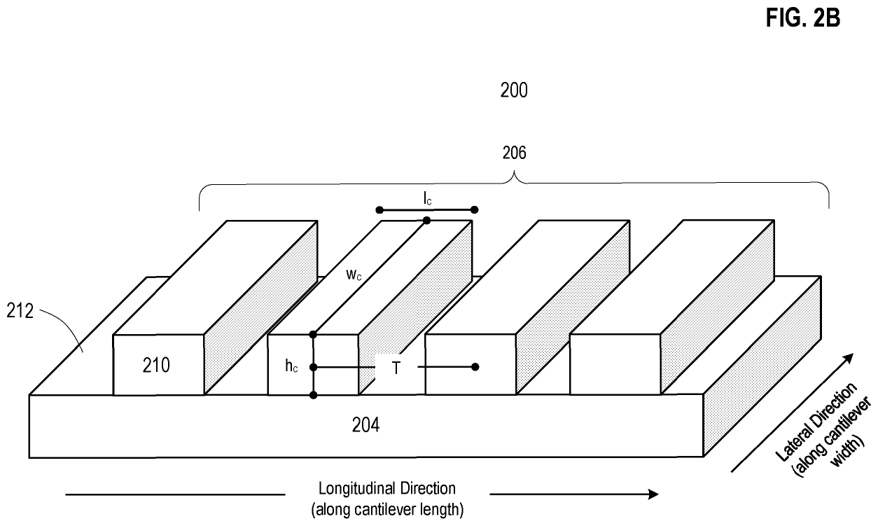

A top-down view and a perspective view of an exemplary cantilever 200 comprising a second dielectric layer 206 that is geometrically patterned atop a first dielectric layer 204 are provided in FIG. 2A and FIG. 2B, respectively. As shown, second dielectric layer 206 may comprise a patterning of crossbars 210 deposited on a surface 212 of first dielectric layer 204. Each crossbar 210 may have a length l_{c}, a width w_{c}, and a height h_{c} relative to surface 212 and may be oriented at an angle θ_{c} relative to the length of cantilever 100.

Dielectric layer 206 may be formed from a dielectric material such as an oxide (e.g., silicon dioxide, aluminum oxide, hafnium dioxide etc.), silicon nitride, or silicon oxy-nitride. During the fabrication of cantilever 100, this dielectric material may be deposited on top of the underlying cantilever layers (e.g., on top of first dielectric layer 204 and the underlying sacrificial layer) and subsequently etched to form crossbars 210. Intrinsic stress may be added to second dielectric layer 206 by varying the density of the dielectric material, by varying the conditions under which second dielectric layer 206 is deposited, and by adding dopants.

Relative to its width w_{c}, the length l_{c} of a given crossbar 210 may be small. For example, the length l_{c} of a given crossbar 210 may be 90%, 80%, 70%, 60%, 50%, 40%, 30%, 20%, or 10% smaller the width w_{c} of the crossbar. In some embodiments, the length l_{c} of a given crossbar 210 is approximately (e.g., is within 1%, 10%, 15%, or 20% of) 0.5, 0.75, 1, 1.25, 1.5, 1.75, 2, 2.25, 2.5, 2.75, or 3 microns In some embodiments, the length l_{c} of a given crossbar 210 is greater than or equal to 0.1, 0.15, 0.2, 0.25, 0.3, 0.35, 0.4, 0.45, or 0.5 μm. In some embodiments, the length l_{c} of a given crossbar 210 is less than or equal to 5, 4.5, 4, 3.5, 3, 2.5, 2, 1.5, or 1 μm. Each crossbar 210 may have the same length l_{c}, or the lengths of crossbars 210 may vary, e.g., may vary along the length of cantilever 100 or along the width of cantilever 100. In some embodiments, the length l_{c} of a crossbar 210 may taper along the width or the height of the crossbar.

A crossbar 210 may be as wide as the underlying layers (e.g., first dielectric layer 204) of cantilever 200 or may be more or less wide than the underlying layers of (e.g., first dielectric layer 204) of cantilever 100. In some embodiments, the width w_{c} of a given crossbar 210 is greater than or equal to 1, 5, 10, 15, 25, 50, 75, 100, 200, 300, 400, or 500 μm. In some embodiments, the width w_{c} of a given crossbar 210 is less than or equal to 1000, 900, 800, 700, 600, 500, or 400 μm. The width w_{c} of each crossbar 210 may affect the amount by which layer 206 can suppress and redirect the lateral strain in cantilever 200 in the longitudinal direction. In some embodiments, each crossbar 210 has the same width w_{c}; in other embodiments, the widths of crossbars 210 vary, e.g., along the length of cantilever 200 or along the width of cantilever 200. In some embodiments, the width w_{c} of a crossbar 210 may taper along the length or the height of the crossbar.

Crossbars 210 may or may not protrude from surface 212. If a given crossbar 210 does not protrude from surface 212, its height h_{c} relative to surface 212 may be negligible. If a given crossbar 210 does protrude from surface 212, its height h_{c} relative to surface 212 may be greater than 0 μm and less than or equal to 0.05, 0.1, 0.15, 0.2, 0.25, 0.3, 0.35, 0.4, 0.45, 0.5, 0.55, 0.6, 0.65, 0.7, 0.75, 0.8, 0.85, 0.9, 0.95, 1, 1.05, 1.1, 1.15, 1.2, 1.25, 1.3, 1.35, 1.4, 1.45, 1.5, 1.55, 1.6, 1.65, 1.7, 1.75, 1.8, 1.85, 1.9, 1.95 or 2 μm. Each crossbar 210 can have the same height h_{c}, or the heights of crossbars 210 may vary, e.g., along the length of cantilever 200 or along the width of cantilever 200. In some embodiments, the height h_{c} of a crossbar 210 may taper along the length or the width of the crossbar.

The angle θ_{c} at which a given crossbar 210 is oriented relative to the length of cantilever 200 may be an angle between a line parallel to the length of cantilever 200 and a line parallel to the width of the crossbar. In some embodiments, a crossbar 210 is patterned such that its width is orthogonal to the length of cantilever 100—i.e., the angle θ_{c} at which the crossbar is oriented relative to the length of cantilever 200 may be approximately 90°. A crossbar 210 can also be patterned such that its width is oriented diagonally with respect to the length of cantilever 100—e.g., the angle θ_{c} at which the crossbar is oriented relative to the length of cantilever 200 may be less than 90° or greater than 90°. In some cases, each crossbar 210 may be oriented at the same angle θ_{c} relative to the length of cantilever 200. In others, the orientations of crossbars 210 may vary, e.g., along the length of cantilever 200 or along the width of cantilever 200. The angle(s) at which crossbars 210 are oriented relative to the length of cantilever 200 may affect the direction in which cantilever 200 deflects when released from the substrate.

The patterning of the plurality of crossbars 210 may be periodic along the length of cantilever 200. That is, the patterning of crossbars 210 may repeat after a given distance T along the length of cantilever 200, where T is the period of the crossbar patterning. If each crossbar 210 has the same geometry and the same orientation relative to the length of cantilever 200, the period T of the crossbar patterning may be the z-dimensional separation distance between analogous points on adjacent crossbars, as illustrated in FIG. 2B. In such cases, the period T may be directly related to the z-dimensional density of crossbars 210. On the other hand, if the geometries or the orientations of crossbars 210 varies along the length of cantilever 200, the period T of the crossbar patterning may be the z-dimensional separation distance between analogous points in repeating crossbar pattern segments. For example, if dielectric layer 206 is divided into repeating segments having the following crossbar pattern:
a first crossbar oriented at a first angle θ_{c1};
a second crossbar oriented at a second angle θ_{c2};
a third crossbar oriented at a third angle θ_{c3},
   then the period T of the crossbar patterning may be the z-dimensional separation distance between analogous points on the first crossbar in a first segment and the first crossbar in a second segment that is adjacent to the first segment.

In some embodiments, the period T of the crossbar patterning is greater than or equal to 0.05, 0.1, 0.5, 1, 1.5, 2, 2.5, 3, 3.5, 4, 4.5, 5, 5.5, 6, 6.5, 7, or 7.5 μm. In some embodiments, the period T of the crossbar patterning is less than or equal to 15, 14.5, 14, 13.5, 13, 12.5, 12, 11.5, 11, 10.5, 10, 9.5, 9, 8.5, 8, or 7.5 μm. In some embodiments, the period T is approximately equal to (e.g., with 1%, 5%, 10%, or 15% of) half of the z-dimensional length of cantilever 200. In some embodiments, the period T is at least 20, at least 30, at least 40, at least 50, at least 60, at least 70, at least 80, at least 90, or at least 100 μm. The period T of the crossbar patterning can remain constant along the length of cantilever 200 or can vary (e.g., increase or decrease) along the length of cantilever 200.

If each crossbar 210 has the same length l_{c}, the duty cycle of the crossbar patterning, defined as the ratio of the crossbar length l_{c} to the period T of the crossbar patterning (Duty Cycle=l_{c}/T) may range between 0 and 1. For example, the crossbar patterning can have a duty cycle in the range 0-0.25, 0-0.5, 0-0.75, or 0-0.99. If second dielectric layer 206 has a crossbar patterning with a low duty cycle (e.g., a duty cycle less than 0.25), second dielectric layer 206 may be capable of redirecting a greater amount of lateral strain in cantilever 100 along the length of cantilever 100; as such, a cantilever having low duty cycle crossbar patterning may, when released from its substrate, deflect along its lengths by a greater amount than a cantilever having a higher duty cycle crossbar patterning.

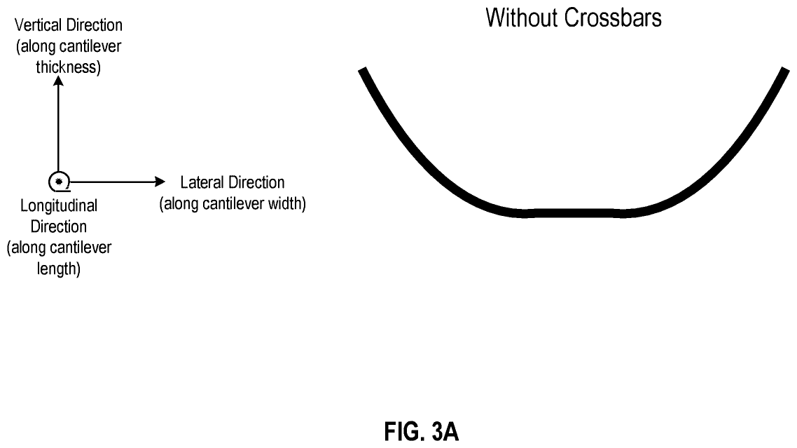

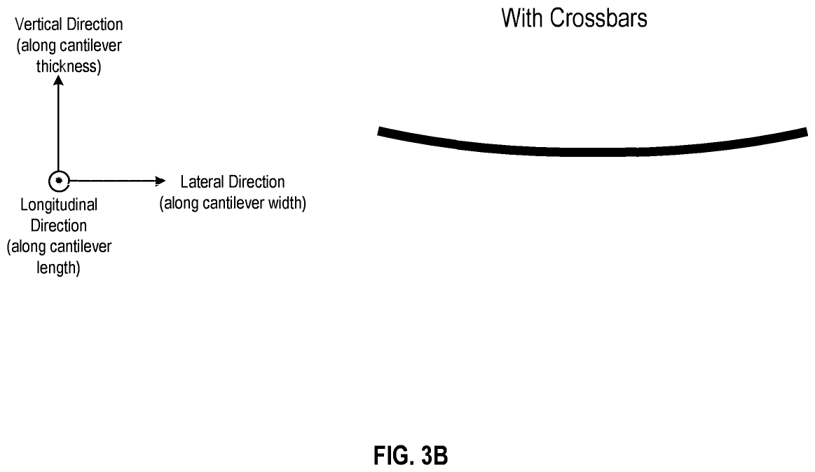

As previously noted, the crossbar patterning of the topmost dielectric layer may, when the cantilever is released from its substrate, redirect lateral strain in the cantilever in a longitudinal direction in order to increase the amount by which the cantilever deflects along its length. FIGS. 3A-3B illustrate qualitative differences in the lateral curvature of a released cantilever that does not have crossbars (FIG. 3A) and the lateral curvature of a released cantilever that does have crossbars (FIG. 3B). As shown, the lateral curvature in a released cantilever with crossbars (FIG. 3B) is suppressed relative to the lateral curvature in a released cantilever without crossbars (FIG. 3A).

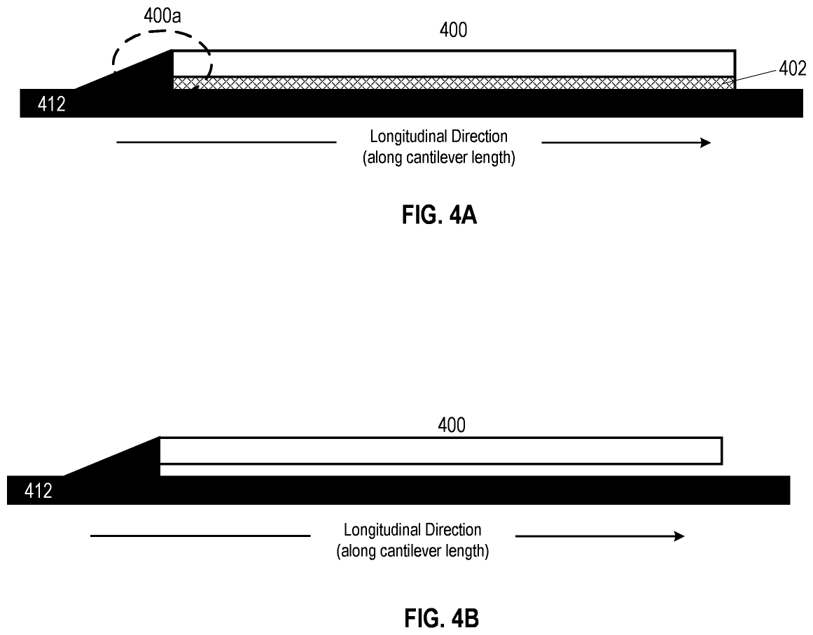

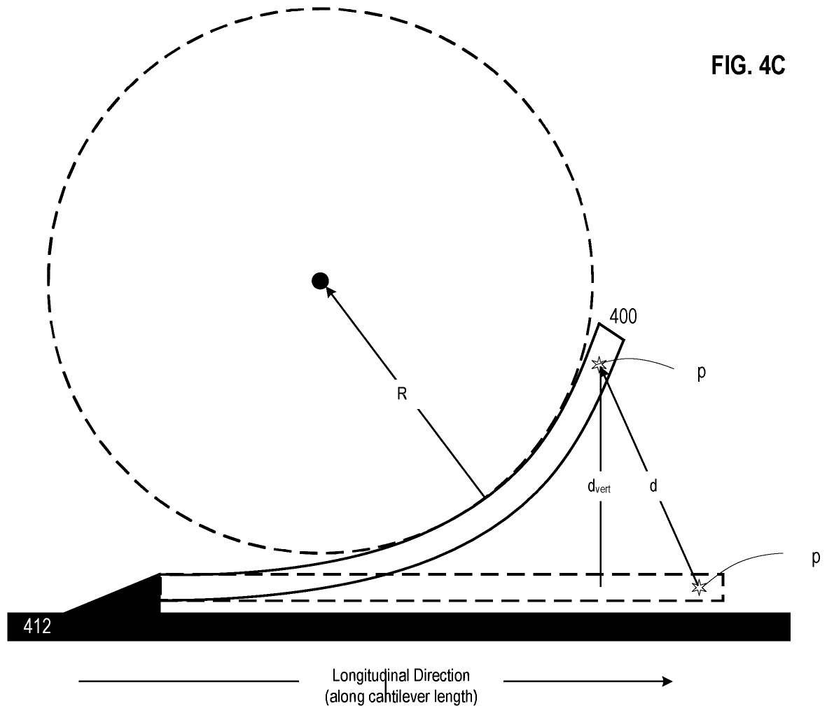

FIGS. 4A-4C depict side views of an exemplary cantilever 400 prior to the removal of its sacrificial layer 402 (FIG. 4A), immediately following the removal of sacrificial layer 402 (FIG. 4B), and after its deflection (FIG. 4C). During the fabrication of cantilever 400, sacrificial layer 402 may be deposited between a substrate 412 and an overlying layer of cantilever 400 (e.g., a first dielectric layer such as layer 104 shown in FIG. 1) to bind cantilever 400 along its length to substrate 412, as illustrated in FIG. 4A. Substrate 412 may be any CMOS-compatible material suitable for wafer-scale fabrication techniques (e.g., silicon). A portion of cantilever 400 (e.g., one end 400a, as shown in FIGS. 4A-4C, or, if more complex curling behavior is desired, another portion along the length of cantilever 400) may be anchored to substrate 412. When sacrificial layer 402 is removed, the length of cantilever 400 may extend from the anchored portion (e.g., end 400a) in a direction parallel to the surface of substrate 412 (FIG. 4B). Cantilever 400 may then deflect relative to substrate 412 due to the differences in the intrinsic stresses of its dielectric layers (e.g., layers 104-106 shown in FIG. 1, layers 204-206 shown in FIGS. 2A-2B), as shown in FIG. 4C. The deflection may be amplified due to a redirection of lateral strain along the longitudinal direction by the geometric patterning of the topmost dielectric layer (e.g., dielectric layer 206 shown in FIGS. 2A-2B) of cantilever 400.

In some embodiments, the geometric patterning of the topmost dielectric layer causes cantilever 400 to deflect along its length in a direction away from the substrate (as illustrated in FIG. 4C). In other embodiments, the geometric patterning of the topmost dielectric layer causes cantilever 400 to deflect along its length in a direction toward the substrate (e.g., causes cantilever 400 to form a semi-circular or semi-ellipsoid arch relative to the substrate). In other embodiments, the geometric patterning of the topmost dielectric layer causes cantilever 400 to twist one or more times along its length to form a (partial) helix. In other embodiments, the geometric patterning of the topmost dielectric layer causes cantilever 400 to twist along its length and to deflect along its length.

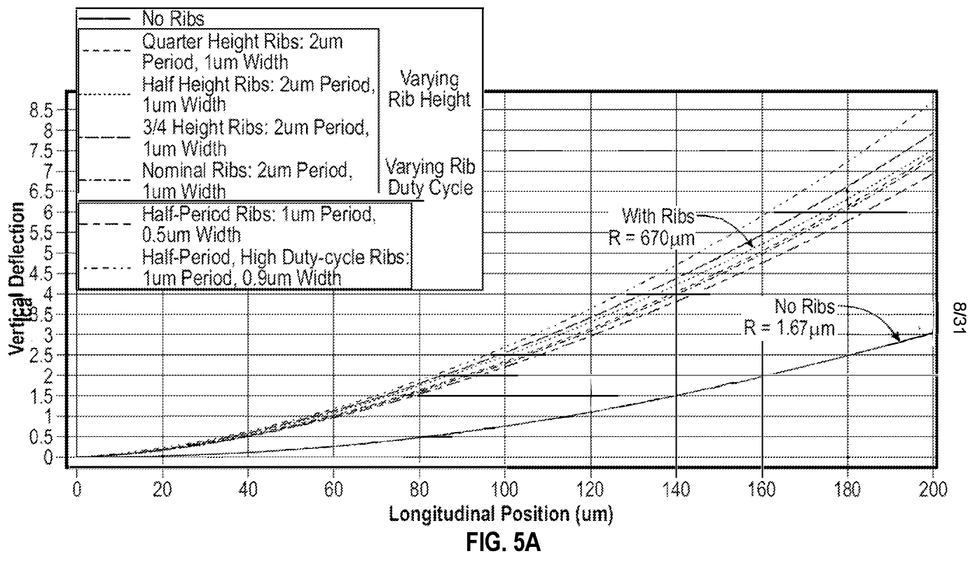

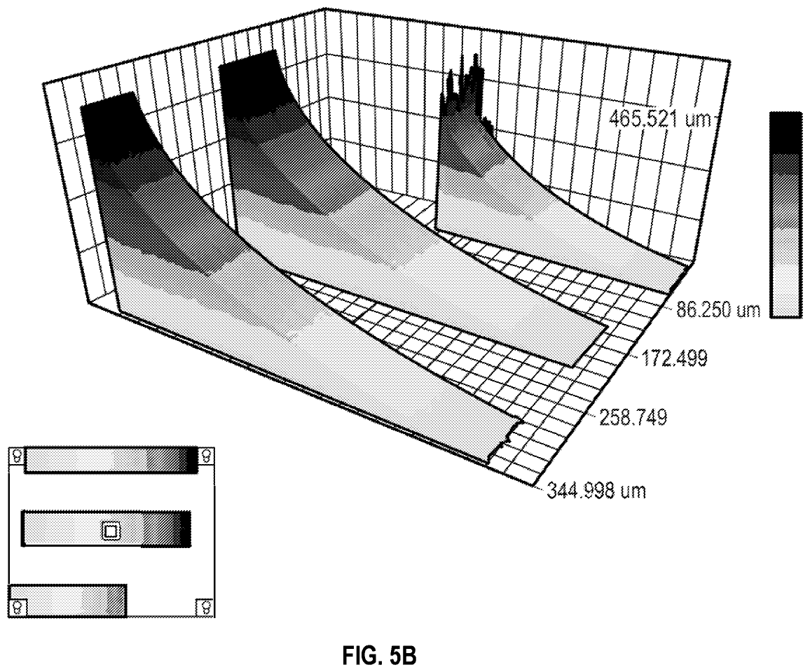

The amount by which cantilever 400 deflects at a given point p along its length when released may be the magnitude of a vector d between a location of point p in the deflected state and a location of point p in the undeflected state (indicated by dashed lines in FIG. 4C). The vertical deflection of cantilever 400 at point p may be given by the vertical component dᵥₑᵣₜ of vector d. In some embodiments, a maximum value of dᵥₑᵣₜ along the length of cantilever 100 may be greater than or equal to 100 microns, 200 microns, 300 microns, 400 microns, 500 microns, 600 microns, 700 microns, 800 microns, 900 microns, or 1000 microns. Example data showing a relationship between crossbar height, crossbar duty cycle, and vertical deflection in a cantilever comprising crossbars oriented at a 90° angle relative to the cantilever length is provided in FIG. 5A. (Note that the term “rib” in FIG. 5A is interchangeable with the term “crossbar” as used herein.)

Various embodiments of the cantilevers disclosed herein may achieve a large vertical deflection over a short longitudinal distance. As illustrated in FIG. 4C, when deflected, cantilever 400 may comprise one or more curved portions. The radius of curvature R of cantilever 400 may be constant or may change along the length of cantilever 400. In some embodiments, a curved portion of cantilever 400 has a radius of curvature R that is greater than or equal to 500, 600, 700, 800, 900, or 1000 μm. In some embodiments, a curved portion of cantilever 100 has a radius of curvature R that is less than or equal to 500, 400, 300, 200, 100, 50, 25, or 10 μm. Example data characterizing the deflected state of a cantilever configured to have a constant radius of curvature is provided in FIG. 5B.

A cantilever can be “programmed” during fabrication to assume a variety of three-dimensional configurations following its release from the underlying substrate by controlling the patterning of the topmost dielectric layer. A cantilever may therefore to be used to form self-assembling curved or helical micro-structures. For example, a cantilever may be used to perform micron-scale origami or kirigami.

### Curving Cantilevers for Photonic Applications

The provided cantilevers can have integrated photonic components and can be configured to be implemented in a photonic system such as a photonic integrated circuit (PIC) chip. For example, a cantilever may include one or more waveguide channels that can receive and transmit optical signals from other photonic devices (e.g., from a laser, from another waveguide, etc.). During fabrication, such a cantilever may be bonded to a substrate of a photonic system (e.g., a substrate of a PIC chip) by its sacrificial layer. The deflection of the cantilever once released may facilitate optical signal transmission and/or receipt via the waveguide channel(s) in the cantilever in two or more dimensions. For example, the cantilever may be used to transmit optical signals from the PIC chip to an off-chip photonic device situated above the PIC chip.

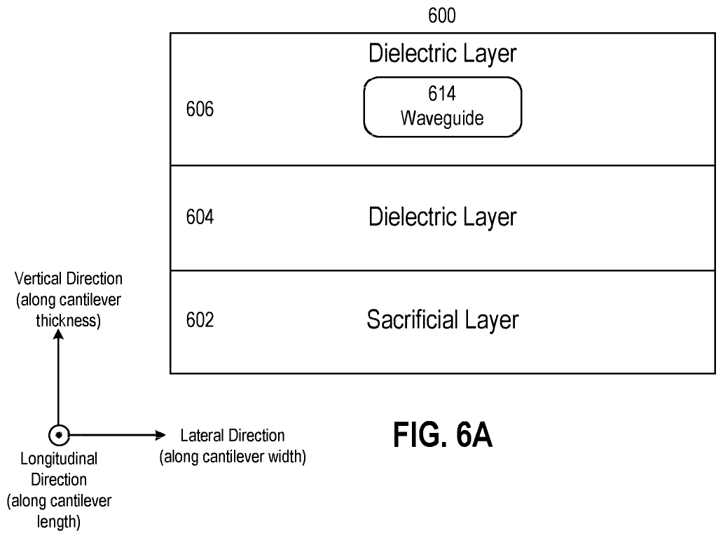

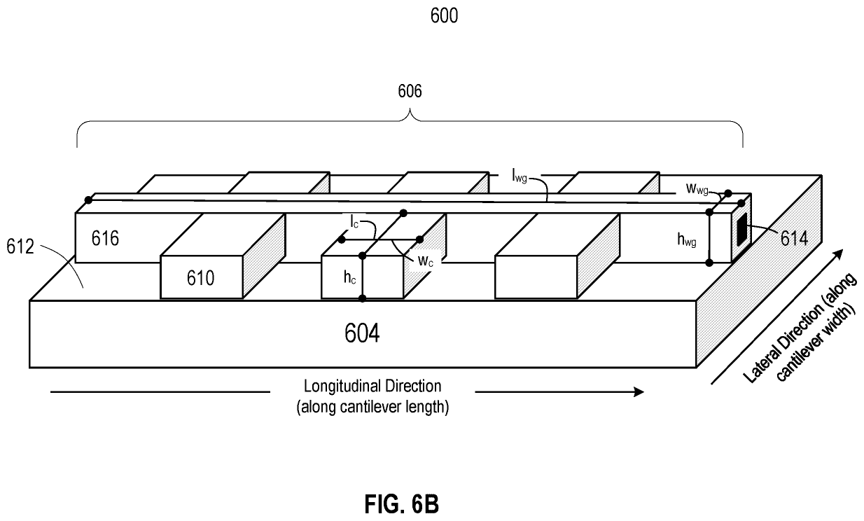

As shown in FIGS. 6A-6B, a waveguide 614 can be oriented along the length of a cantilever 600 and can form a channel within a second, topmost dielectric layer 606 of cantilever 600. Waveguide 614 may be formed using a dielectric material with low optical loss (e.g., optical loss of less than 1 dB/cm). Waveguide 614 may be oriented parallel to the length of the cantilever (e.g., oriented along the longitudinal direction) and can be positioned proximally or distally to the center of cantilever 600.

Dielectric layers 604 and 606 (like, e.g., dielectric layers 104 and 106 shown in FIG. 1) may have different intrinsic stresses. During fabrication, cantilever 600 may be anchored to the substrate of a photonic system (e.g., the substrate of a PIC chip) by a sacrificial layer 602. When sacrificial layer 602 is removed, the difference between the intrinsic stress of dielectric layer 604 and the intrinsic stress of dielectric layer 606 may cause cantilever 600 to deflect along its length, thereby curving waveguide 614.

Layer 606 can be geometrically patterned such that, when sacrificial layer 602 is removed, the longitudinal deflection of cantilever 600 (and, therefore, of waveguide 614) is amplified and lateral deflection of cantilever 600 is suppressed. For example, layer 606 can comprise a plurality of crossbars 610 (FIG. 6B). A dielectric cladding material 616 that matches the material used to form crossbars 610 may coat waveguide 614. Cladding 616 may have a length l_{wg}, a width w_{wg}, and a height (relative to a surface 212 of second dielectric layer 106) h_{wg}. The total height of waveguide 614 and cladding 616 may be similar to the heights of the surrounding crossbars 610. The amount of cladding 616 coating waveguide 614 may be a minimum amount necessary to protect waveguide 614 from damage. In some embodiments, the amount of cladding 616 on either side of waveguide 614 is less than or approximately equal to 0.25, 0.5, 0.75, or 1 μm.

Crossbars 610 may be patterned on one side of waveguide 614 or on both sides of waveguide 614. If crossbars 610 are patterned on both sides of waveguide 614, the crossbar patterning on one side of waveguide 614 may differ from crossbar patterning on the other side of waveguide 614. When released, cantilever 600 may form shapes of varying complexities.

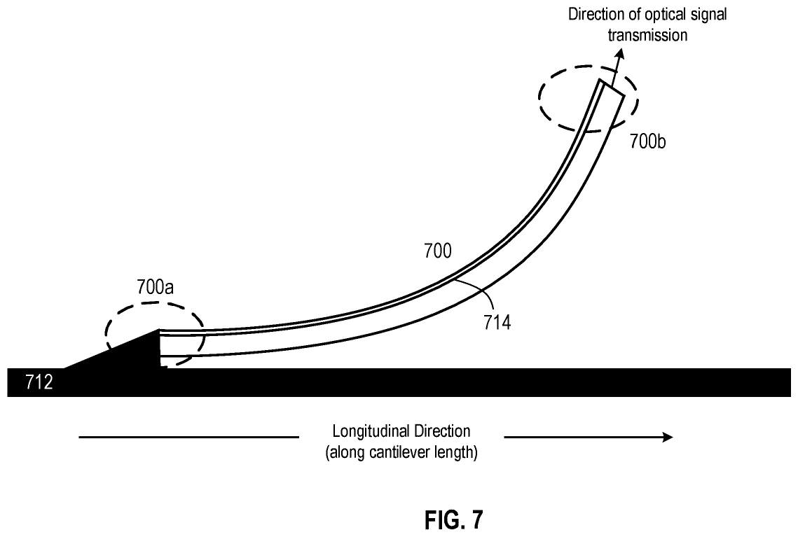

FIG. 7 provides a side view of a released cantilever 700 that is patterned with a waveguide 714. The substrate 712 to which end 700a of cantilever 700 is anchored may host one or more optical components (e.g., one or more components of a PIC chip). At the anchored end 700a of cantilever 700, waveguide 714 may be optically coupled to one of these optical components. Alternatively, waveguide 714 may extend past the anchored end 700a onto substrate 712. At the unanchored end 700b of cantilever 700, waveguide 714 may be optically coupled to an optoelectronic component that is not hosted on substrate 712 (e.g., an off-chip component, such as a component of a separate PIC). Optical signals can be received by waveguide 714 (or, more specifically, by the portion of waveguide 714 contained in cantilever 700) at either end 700a or 700b and may propagate along the length of cantilever 700. The optical path followed by optical signals propagating through waveguide 714 may depend on the shape that cantilever 700 obtains upon release from substrate 700.

A cantilever with integrated photonic components such as cantilever 600 or cantilever 700 can be fabricated on the same PIC as other active broadband integrated photonic components. For example, a cantilever with integrated photonic components can be fabricated on a PIC with Mach-Zehnder interferometers (MZIs), couplers, and ring resonators. Accordingly, light that is coupled into a waveguide in the cantilever (e.g., waveguide 614) or transmitted out of the waveguide can be controlled (e.g., modulated) without being transmitted off-chip.

### Active Curving Cantilevers

The provided cantilevers can be configured such that their deflection is actively controllable. That is, rather than being configured to deflect and remain deflected following its release from its substrate, a cantilever may be configured to deflect on-demand. Control of the deflection of a cantilever may be binary (e.g., a cantilever may be switchable between an undeflected state and a single deflected state), discrete (e.g., a cantilever may be switchable between an undeflected state and two or more distinct deflected states), or continuous (e.g., a cantilever may be adjustable between a continuum of configurations between an undeflected state and a fully deflected state).

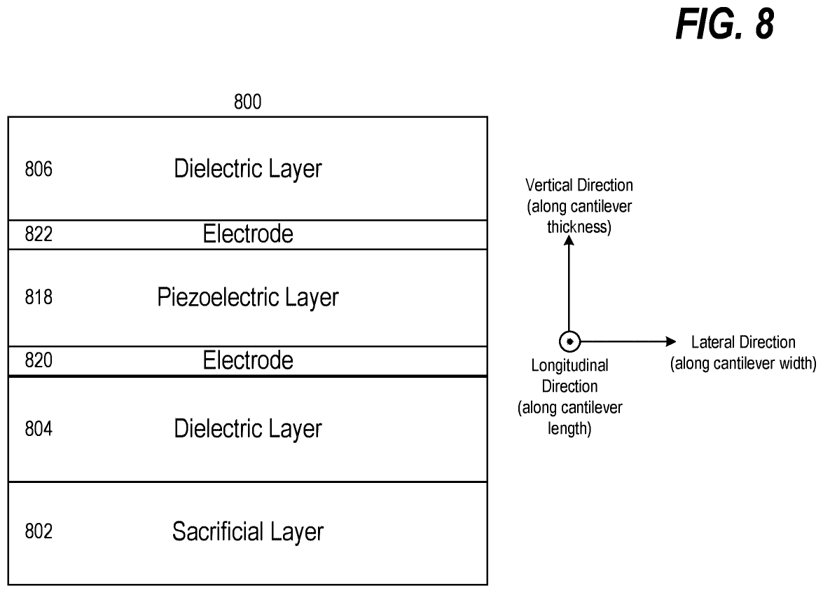

A cross-sectional view of exemplary actively controllable cantilever 800 is shown in FIG. 8. In this embodiment, cantilever 800 comprises a pair of dielectric layers 804 and 806 having differing intrinsic stresses as well as a layer 818 of piezoelectric material overlying a first dielectric layer 804. Sandwiching piezoelectric layer 818 may be a pair of conductive electrodes 820-822. A second dielectric layer 806 may overlay electrode 822. Electrodes 820-822 may be electrically connected (e.g., by wires or conductive traces in the substrate to which cantilever 800 is anchored) to a voltage source (e.g., a battery, an AC/DC power supply, etc.). Applying a voltage across piezoelectric layer 818 using the voltage source may cause piezoelectric layer 818 to mechanically deform. If the voltage is applied to piezoelectric layer 818 when sacrificial layer 802 is removed and cantilever 800 is released, the mechanical deformation of piezoelectric layer 818 may cause cantilever 800 to deflect along its length.

Piezoelectric layer 818 may be formed from a piezoelectric material having an intrinsic tensile stress. More generally, the piezoelectric material that constitutes piezoelectric layer 818 may have an intrinsic stress that is more positive than the intrinsic stress of the underlying dielectric layer 804. Suitable piezoelectric materials include (but are not limited to) aluminum nitride, aluminum scandium nitride, and barium titanate.

Electrodes 820-822 may have negligible intrinsic stress and may be deposited on piezoelectric layer 818 in layers that are as thin as possible while still allowing necessary conduction of electric current and generation of voltage. In some embodiments, each electrode is less than 300, less than 250, less than 200, or less than 150 nm thick. Suitable electrode materials include (but are not limited to) aluminum and copper.

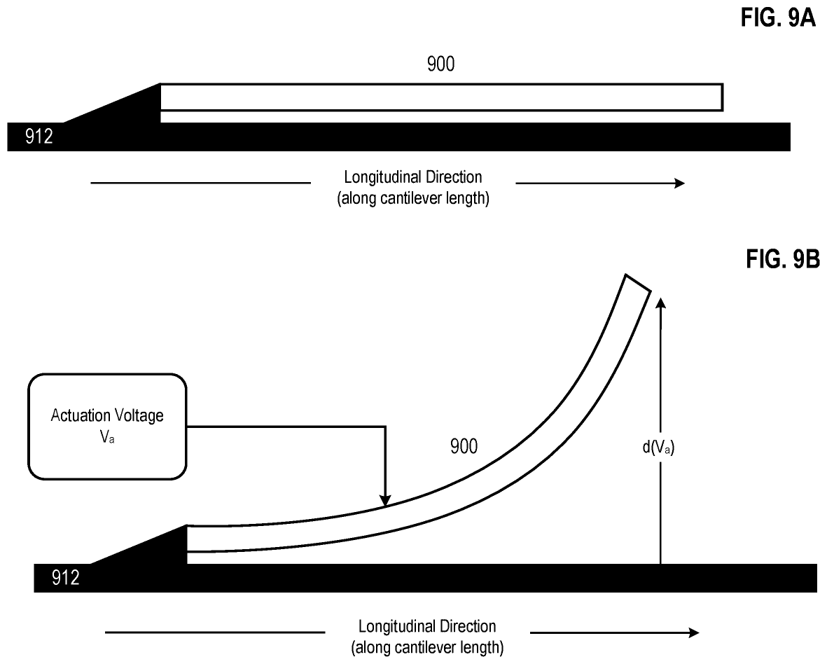

FIGS. 9A-9B depict side views of a piezoelectrically actuated cantilever 900. Cantilever 900 may comprise a piezoelectric layer structure (not shown) similar or identical to that of cantilever 800 shown in FIG. 8. When cantilever 900 is released from its substrate 912 but no voltage is applied across the piezoelectric layer, cantilever 900 may be in an undeflected state wherein the length of cantilever 900 is parallel to substrate 912 (FIG. 9A). However, when an actuation voltage Va is applied across the piezoelectric layer, the mechanical deformation of the piezoelectric material may cause cantilever 900 to deflect along its length relative to substrate 912 (FIG. 9B). Cantilever 900 may remain in a deflected state until the actuation voltage is turned off and the piezoelectric layer returns to its unactuated state, at which point cantilever 900 may revert to its undeflected configuration.

The amount by which cantilever 900 deflects, along with the direction in which the deflection occurs, may depend respectively upon the magnitude and sign of the actuation voltage Va. A negative actuation voltage may cause cantilever 900 to deflect in a first direction and a positive actuation voltage may cause cantilever 900 to deflect in a second direction that is opposite to the first direction. In some embodiments, the voltage source may be configured to apply one or more discrete actuation voltages, each of which may drive cantilever 900 into a distinct deflection state.

### Active Curving Cantilevers for Photonic Applications

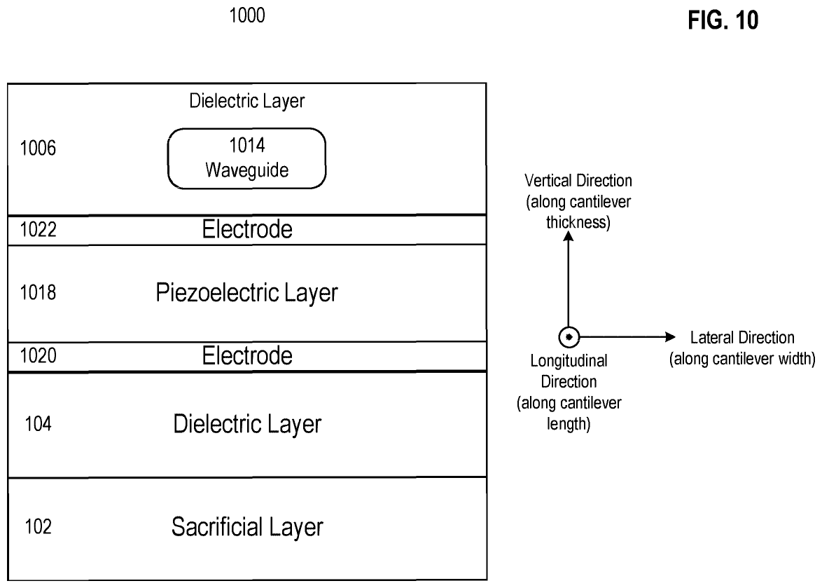

Active control of cantilever curvature may be particularly useful for cantilevers that are components of photonic systems. As shown in FIG. 10, a cantilever 1000 can include both a waveguide 1014 (patterned within a top dielectric layer 1006) and a piezoelectric layer 1018. Varying the actuation voltage applied across piezoelectric layer 1018 may cause cantilever 1000—and, as a result, waveguide 1014—to sweep through one or more deflected states. In each deflected state, waveguide 1014 may optically couple to a different optoelectronic component. Cantilever 1000 may therefore function as an optical switch that enables optical signals to be selectively coupled into or selectively received from multiple different optoelectronic devices.

Driving an active curving cantilever such as cantilever 1000 using an alternating current (AC) actuation voltage may significantly amplify the beam output range of the cantilever waveguide.

The subsequent sections provide various (non-limiting) example applications of the cantilevers described herein.

### Example 1: Origami

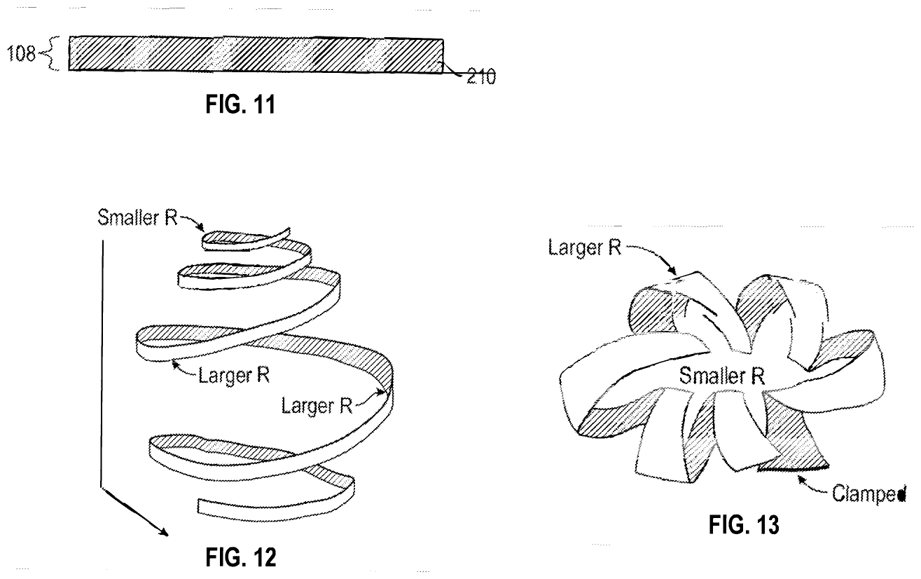

A cantilever can be deterministically configured to assume a helical structure when released by patterning its topmost dielectric layer with crossbars that are oriented diagonally with respect to the cantilever length, as illustrated in FIG. 11. More intricate three-dimensional shapes such as those depicted in FIGS. 11, 12, and 13 may be obtained by patterning the crossbars such that the radius of curvature R of the helix varies along the length of the cantilever when the cantilever is released. For example, a ball may be created by patterning the crossbars such that, when the cantilever is released, the radius of curvature R of the cantilever is starts out relatively small near one end, increases along the cantilever length, and then decreases again toward the other end (FIG. 12). A toroid may be created by modulating the radius of curvature R at the same spatial period as the helical twist such that a larger radius R appears at the same point in the twist, causing the helix to turn and, eventually, close on itself (FIG. 13). Additional shapes can be obtained via similar modulation of the stress magnitude and directionality. Complex structures may be self-assembled by combining multiple cantilevers configured to obtain more basic shapes.

### Example 2: Micron-Scale Gripping Actuators

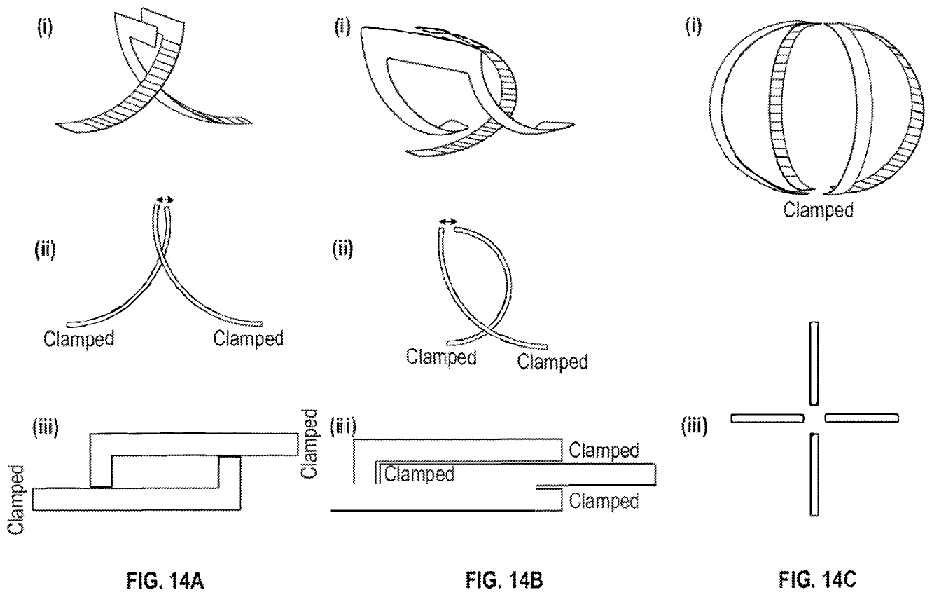

Micron-scale gripping actuators can be formed by counter-posing two or more cantilevers, as shown in FIGS. 14A-14C. The topmost dielectric layers on the cantilevers in a gripping actuator may be patterned with crossbars such that, when the cantilevers are released, the cantilevers curl toward one another. The deflection of the cantilevers in a gripping actuator may be piezoelectrically controlled so that the gripping actuator can be selectively opened and closed. These actuators may be implemented in micro-robotic systems.

### Example 3: Sideways-Twisting Cantilever with Waveguide

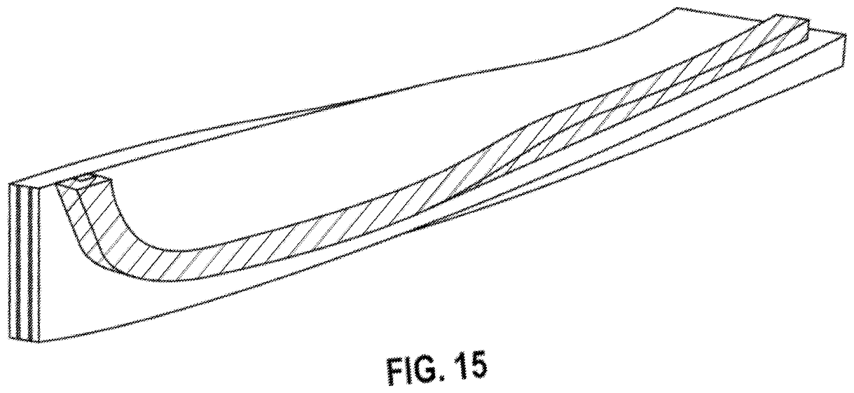

The downward stress of the waveguide channel in a piezoelectrically actuated cantilever with a waveguide may generate a stress gradient that causes twisting which allows the edge opposite the waveguide to turn up, as illustrated in FIG. 15. In FIG. 15, the waveguide (shown in hashing) is offset from the center of cantilever, creating a stress gradient that causes the side of the cantilever opposite the waveguide to twist upward with respect to the side of the cantilever with the waveguide

### Example 4: “Candy-Cane” Photonic Coupler

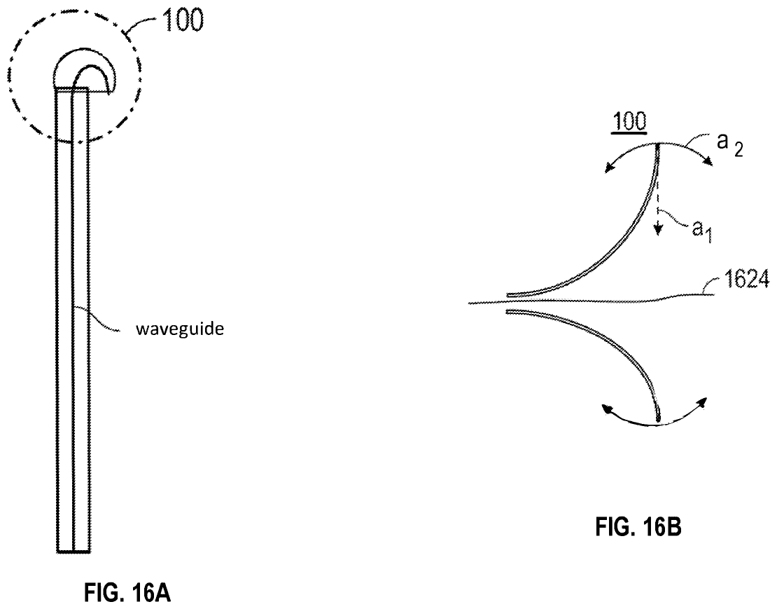

A piezoelectrically actuated cantilever with a waveguide can be used to form a “candy-cane”-shaped photonic coupler, as illustrated in FIGS. 16A-B. The cantilever may be used to direct the waveguide toward a reflective substrate (1624 in FIG. 16B), as indicated by arrow a₁. An optical signal directed to the reflective substrate by the waveguide may reflect perpendicularly to the reflective substrate. This embodiment may thus be used to correct for optical aberrations by shifting of the vertical location of the waveguide output by actuating the cantilever, as indicated by arrow a₂.

### Example 5: “Stair-Step” Photonic Coupler

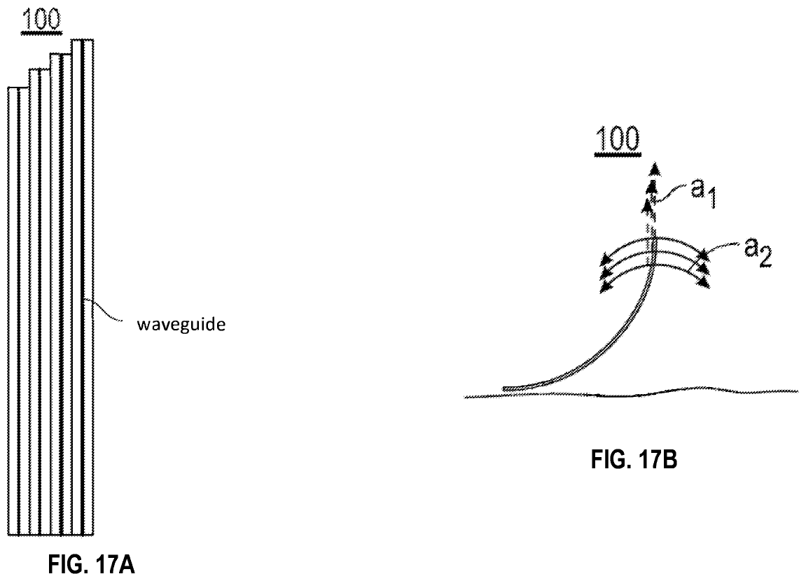

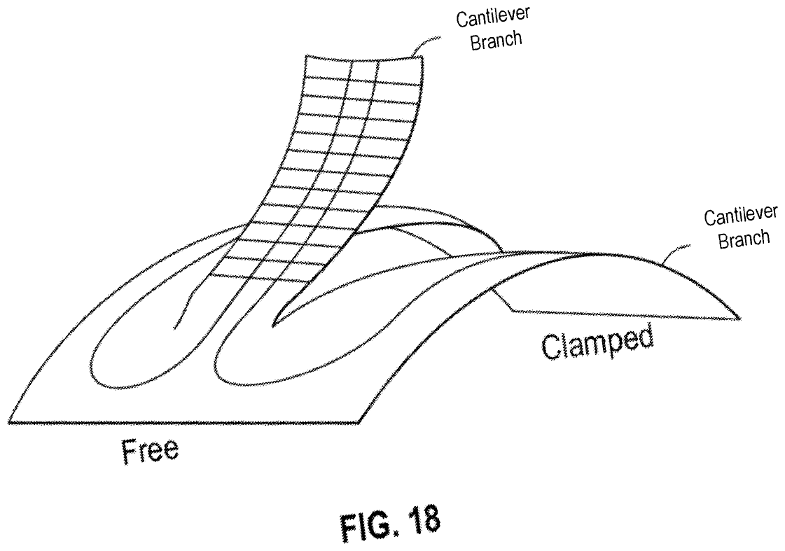

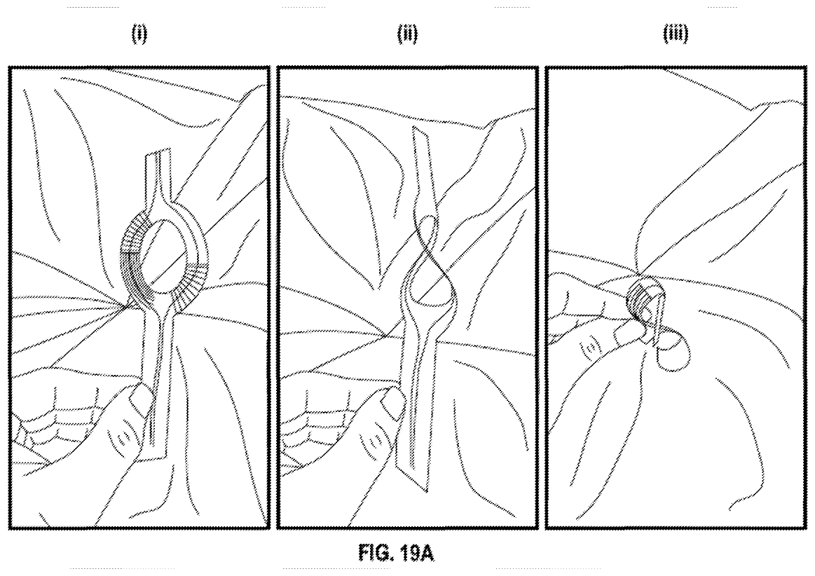

A piezoelectrically-actuated cantilever may be patterned with multiple waveguides of varying lengths to form a “stair-step” photonic coupler, as shown in FIGS. 17A-17B. The cantilever may be etched so that, from a top-down perspective, the emitting end of the cantilever has “stair-step” shape. When the cantilever is actuated (as indicated by arrows a₂), each waveguide may emit at a different vertical location relative to the cantilever's substrate (indicated by arrows a₁). Changing the waveguide through which an optical signal is transmitted may change the vertical output location of the optical signal which may, in turn, adjust the focal plane of the optical signal. This may enable the optical beam to be focused at another location.

### Example 6: Angle-Boosted Cantilever

A cantilever patterned with crossbars oriented orthogonally to its length may deflect vertically along its length when released. The vertical deflection of such a cantilever may be enhanced over a shorter longitudinal distance by fabricating cantilever such that it branches from a downward-bending, bridge-shaped cantilever, as shown in FIG. 18. The bridge-shaped cantilever branch may comprise one clamped end that is anchored to a substrate as well as one free end. The bridge-shaped cantilever branch may comprise a top oxide and nitride coating that forces the branch to arch downward (e.g., toward a substrate). The free end of the bridge-shaped cantilever branch may be oriented at a non-zero angle relative to the substrate. The cantilever branch that deflects vertically away from the substrate may initially be oriented at the same non-zero angle relative to the substrate as the bridge-shaped branch, i.e., may initially be vertically deflected relative to the substrate by a non-zero amount. This vertically deflecting cantilever branch may achieve greater vertical deflection over a shorter distance.

### Example 7: Piezoelectric Control of Cantilever Twist and Torsion

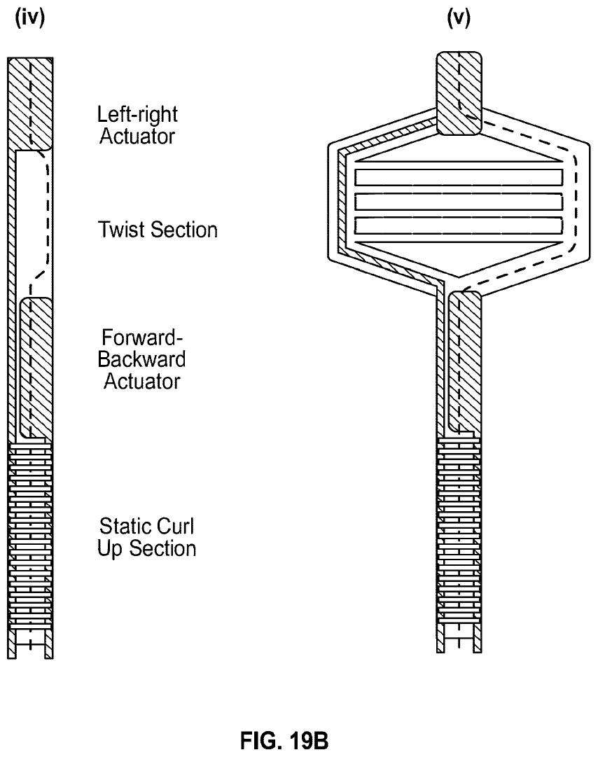

FIG. 19A-B depicts examples of helically-twisted, piezoelectrically-actuated cantilever structures. In these examples, motion along the x-dimensional direction is achieved by twisting the cantilever body by 90° using a first piezoelectric actuator and driving lateral motion using a second piezoelectric actuator. This may be achieved by creating a double-helical section wherein the stress of the crossbars is engineered such that the two branches first bend in away from one another, then bend toward one another. As shown, this may be achieved with one branch having crossbars in the lateral direction while the other has crossbars in the longitudinal direction.

The helically-twisted cantilever structures can be used to form a Z-actuator. Such an actuator may comprise four distinct sections: an initial upward bending section with orthogonally-oriented crossbars, a stress-neutral actuator section that moves the tip longitudinally, a helical or twist section which rotates the cantilever by 90 degrees about its longitudinal axis, and a second stress neutral section that moves the tip laterally. Such structures can also be combined with the angle-boosting structures described in Example 6.

Diagrams (i)-(iii) in FIG. 19A depict demonstrations of shapes for helically-twisted, piezoelectrically-actuated cantilever structures.

Diagrams (iv) and (v) in FIG. 19B depict different components of twisting piezoelectrically-actuated cantilever structures. In diagram (iv), a first piezoelectric component runs up the left side of the cantilever and actuates a central section of the cantilever. A twist section of the cantilever twists due at least in part to the waveguide (shown by a dashed line) being offset from the center of the cantilever in this section. Finally, a second piezoelectric component runs up the right side of the cantilever and actuates a distal section of the cantilever (at the top of the figure). In diagram (v), a similar arrangement is provided, except that the waveguide is routed dramatically off-center to the right from the center-line of the cantilever, and the second piezoelectric component is routed symmetrically dramatically off-center to the left from the center-line of the cantilever; this arrangement may provide increased twisting.

### Example 8: Ball-Lens Terminated Cantilever

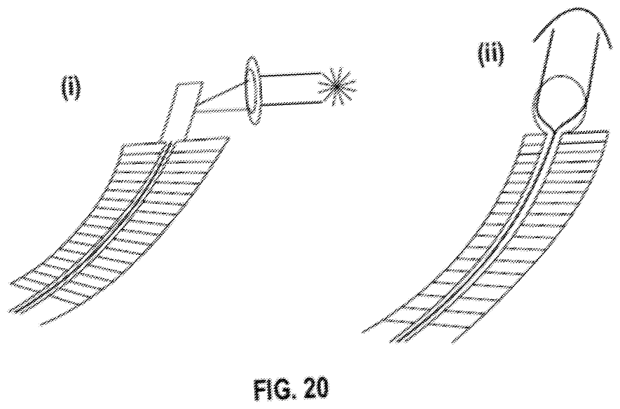

FIGS. 20A-B shows a ball-lens-terminated cantilever. This embodiment may provide direct collimation of output light from waveguides on the cantilever without requiring a bulk objective or lens above the chip to collimate and direct the output beam. Diagram (i) shows a fabrication process in which material for forming a ball lens is melted onto a tip of the cantilever. Diagram (ii) shows the cantilever with ball lens tip after fabrication.

### Example 9: Periodic Optical Switches

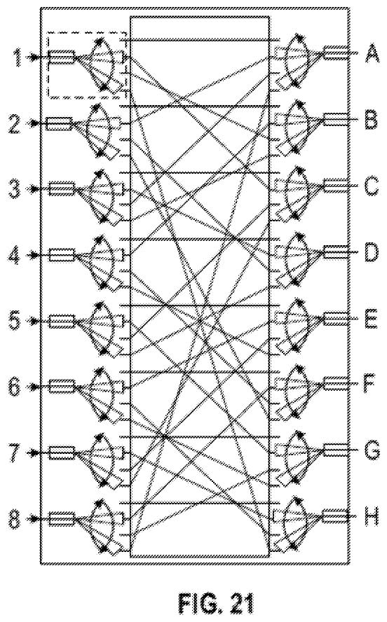

A piezoelectrically-actuated cantilever with a waveguide may be used as 1×N optical switch, as shown in FIG. 21. The cantilever may be adjusted between N distinct deflected states by applying varying actuation voltages across the piezoelectric layer. In each deflected state, the waveguide may optically couple to a different output.

### Example 10: Photonic Cantilever with Low Output Divergence

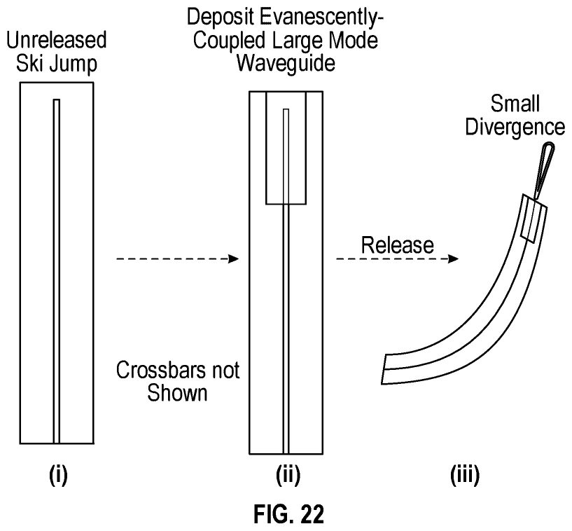

FIG. 22 shows techniques for creating low output divergence photonic cantilevers. Diagram (i) shows an unreleased cantilever. Diagram (ii) shows depositing an evanescently-coupled large mode waveguide. Diagram (iii) shows release of the cantilever and small divergence from the waveguide. As shown, an evanescently coupled large mode waveguide may be deposited at an output end of a waveguide that is patterned on a cantilever. Coupling between the cantilever waveguide and the large mode waveguide may result in low divergence output from the cantilever waveguide.

### Example 11: Beam Steering and Routing of Laser Light in a Photonic Integrated Circuit

In a piezoelectrically-actuated cantilever with a waveguide, crossbars can be patterned at a number of crossbar widths and duty cycles to achieve the enhanced curling. In particular, keeping the crossbars relatively thin (e.g., 1 μm) but increasing the crossbar period from (e.g., from 2 μm to 8 μm) may enhance upward curling for the same length and width of cantilever. This level of curling enhancement may allow at least two waveguides in an array on a single cantilever to in parallel or in sequence to direct light out-of-plane on and off a photonic integrated circuit (PIC) from any location on the chip where such a cantilever is fabricated. Multiple wavelengths, polarizations, laser sources, or photon sources (e.g., from qubit color centers) can be routed simultaneously off chip. The vertical waveguide input/output may have greater independence from wavelength/frequency and polarization of light compared to gratings for on/off PIC coupling. Further optimization of the crossbar geometry to balance re-direction of strain from the width to along the length (waveguide direction) of the cantilever with minimized top oxide strips that can also cause downward curling of the cantilever could further decrease the length of cantilever needed to achieve verticality, thereby improving stability of the device and increasing resonant drive frequencies. Such devices may have applications in multi-color imaging/projection, and the initialization/readout of prototypical qubits (color centers) in diamond.

### Example 12: Resonant Driving of Near-Vertical Cantilevers

A piezoelectrically-actuated cantilever with a waveguide that is nearly-vertically deflected can be driven at resonance to enable significant enhancement of the individual modes accessible for beam steering and control. Driving at one of the higher order modes may maximize the x-dimensional displacement of the beam output with minimized deflection in the y-dimensional direction. This may optimize the cantilever's use as a beam steering device. The cantilevers can be driven on and off resonance up to megahertz frequencies for many hours without degradation.

### Example 13: High-Speed Optical Pulsing for Qubit Control

A piezoelectrically actuated cantilever with a waveguide can be driven with an AC signal once curled to quickly and directly route light output from the waveguide onto diamond chiplet containing via color centers or to route the light via a lens system to the diamond chiplet to quickly pulse light on and off for initialization and readout of the color center. With multiple parallel waveguides on the cantilever, color centers in multiple diamond waveguides can be controlled for readout along the length of the waveguide.

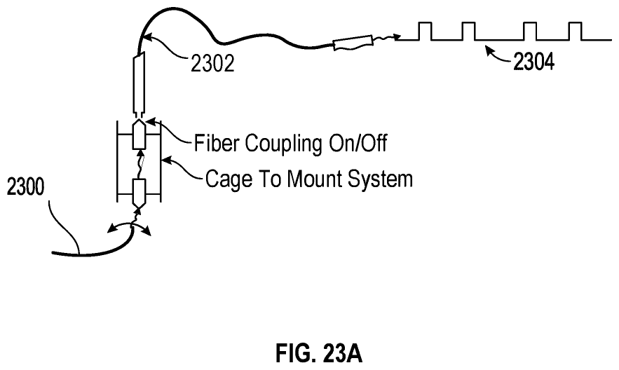

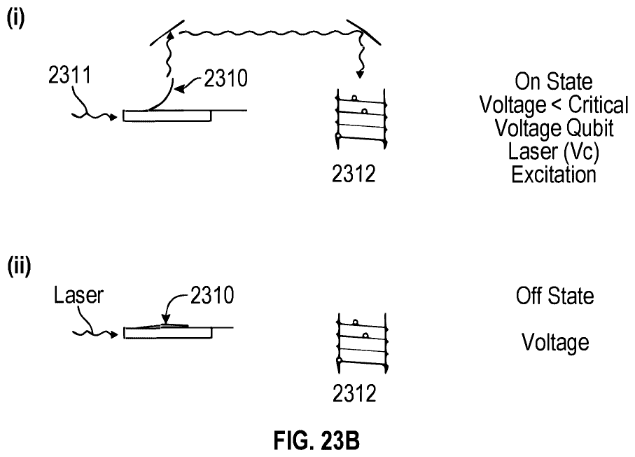

FIG. 23A shows a photonic integrated chip with a cantilever with waveguide 2300, curled 90 degrees upward, directing light vertically out of the chip. Above the PIC chip is a lens or objective to collimate the output beam of light. The light is then routed to a second lens or objective that couples the light to an optical fiber 2302. The optical fiber is routed to a desired location with a collimating lens at the appropriate end. This light can be sent to any desired location. If the cantilever is driven at high speed back and forth, the light out of the cantilever will at one point in time be coupled into the optical fiber to the output on the other end. At other points in time, no light will be coupled and, as a result, there will be light at the other end of the optical fiber. The cantilever can be driven via piezo-actuation at a desired frequency to create pulses of light 2304 at different lengths and periods at the far end of the optical fiber. Driving of the cantilever back and forth can thus be used to modulate the coupling to the optical fiber to form the pulse train 2304. This may be useful for generating short pulses of light, similar to acousto-optic modulators, the latter of which are typically commercial bulky devices. The pulses of light could be used to optically initialize and read out the quantum states of solid-state qubits such as color center atomic defects in diamonds. The pulses may also be used in information transfer of 0s and 1 corresponding to no light (0) and a pulse of light (1).

Referring to FIG. 23B, some cantilever devices may exhibit a behavior wherein, above a certain piezo-voltage threshold, the cantilever 2310 snaps down into the plane of the photonic integrated circuit (as shown in diagram (i)). When the voltage is decreased below this threshold, the cantilever 2310 returns to its original position (as shown in diagram (ii)). This may allow for a binary switch of on and off for the cantilever. When the cantilever is pointing vertically upward as in diagram (i), the light from a laser source 2311 can be directed via lenses and mirrors onto a diamond chiplet 2312 that contains color center atomic defect qubits. The light can be used to initialize and read out the quantum state of the qubits. By using this binary switch behavior, pulses of light can be sent at desired times in a quantum control sequence to control the qubits on the diamond chiplet. The snapping behavior could also be used just to set up a digital pulse train of 0s and 1s for information transfer via the two binary states of the cantilever being curled upward and when the cantilever is snapped into the plane of the chip. Diagram (i) shown an ON state of a PIC, where voltage is below a threshold voltage amount and chiplet 2321 is excited, and diagram (ii) shows an OFF state of the PIC, where voltage is above the threshold voltage amount and the chiplet 2321 is not excited.

### Example 14: Top-Down and Edge Excitation of and Collection from Qubit Color Centers

A piezoelectrically-actuated cantilever with a waveguide may be used for more efficient control of prototypical qubit color centers relative to photonic integrated circuit (PIC) edge excitation and collection or top-down confocal excitation and collection. The boundary of the waveguide output on the curled cantilever can be repeatedly defined to high fabrication fidelity and precision relative to cleaving of PICs for edge coupling. This may allow for outputs off-PIC anywhere on the PIC without requiring long waveguides to route all photons to the edge of the chip.

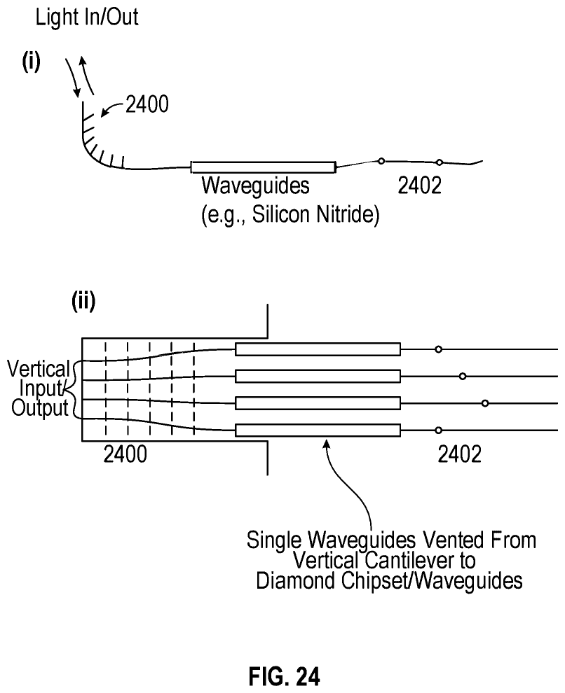

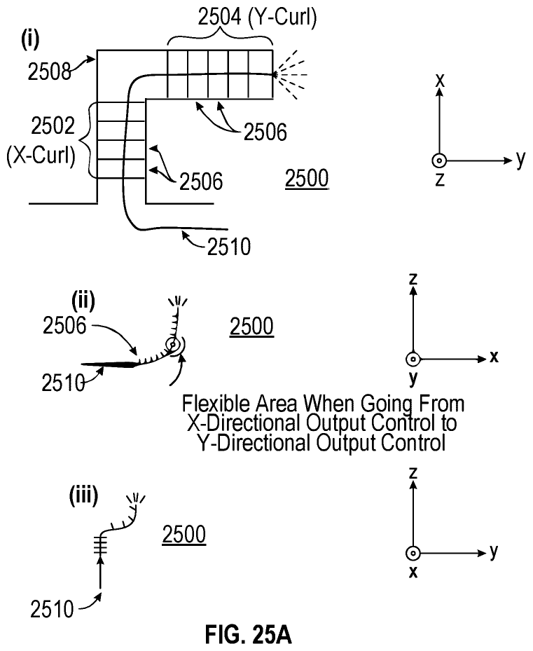

FIG. 24 shows an example whereby laser light is input into one or more waveguides at the end of the cantilever 2400. The light is routed down the waveguides onto the plane of the chip. The waveguides are then coupled to waveguides on a diamond chiplet 2402 that contain the prototypical qubit color centers. The light interacts with the color center. The color center will emit light in response that can go back through the waveguides, up the cantilever and be read at the output of the cantilever. Therefore, the cantilever can be used as a more efficient method to initialize and readout the quantum state of the color center qubit compared to the other methods listed in Example 15. The example embodiment in FIG. 24 has an array of four waveguides on the cantilever, sending control signals to qubits in four different diamond arrays. This is to demonstrate the scalability of the device to control multiple color center qubits via different channels on the same cantilever.

### Example 15: Two-Dimensional Control of Cantilever Segments

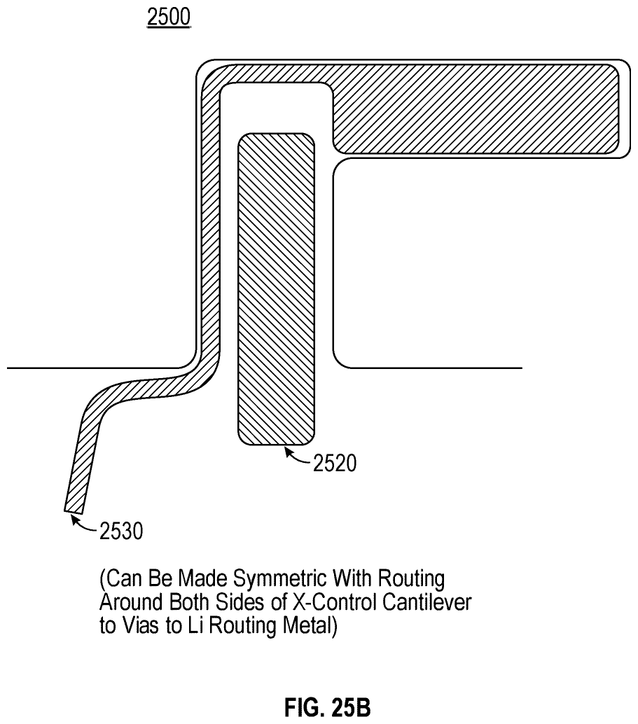

FIG. 25A-25B depict cantilevers 2500 with two independent directionally controlled segments 2502 (x-curl) and 2504 (y-curl). The cantilever segments may be orthogonal to each other. Each segment may comprise crossbars 2506 to ensure rigidity. A non-crossbar “flexture” region 2508 may connect the two segments. If the segments are patterned with waveguides 2510, and each segment curls at 45°, a total angle up and output of waveguides from plane of chip may be at least 60°. Such a cantilever may be implemented on a photonic integrated circuit on angle mounted stage at approximately 24° relative to flat ground or angle objective at 24° relative to a standard vertical location above the photonic integrated chip. This design can allow independent control in two perpendicular directions for beam steering. Diagrams (i)-(iii) in FIG. 25A show three different cartesian views of cantilever 2500. FIG. 25B shows piezo-stack control sections of cantilever 2500. As shown, electrode piezo-stack 2520 may control segment 2502, and electrode piezo-stack 2530 may control segment 2504. In some embodiments, electrode piezo-stack 2530 may be made symmetric with routing around both sides of electrode piezo-stack 2520.

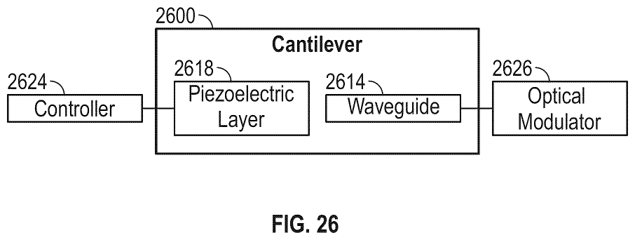

FIG. 26 shows a block diagram of an exemplary system for driving a piezo-actuated cantilever 2600. Cantilever 2600 can comprise the same layers as cantilever 100 of FIG. 10. Piezoelectric layer 2618 may be driven by a controller 2624 that is configured to generate AC signals. In some embodiments, controller 2624 comprises a function generator or an arbitrary waveform generator. In other embodiments, controller 2624 enables digital signal driving. For example, controller 2624 can generate the AC signals using a clock running on an embedded processor, a field programmable gate array (FPGA), a phase lock loop (PLL), or a voltage-controlled oscillator (VCO). A digital controller may simplify the electronic control of cantilever 2600 and increase the scalability of the system.

When cantilever 2600 is driven with AC voltages of specific frequencies, cantilever 2600 may demonstrate one or more y-dimensional resonances (at frequencies ω_{y}) and one or more x-dimensional resonances (at frequencies ωₓ). This may enable the waveguide tip of cantilever 2600 to be moved both in the x and y dimensions. The frequencies at which cantilever 2600 demonstrates the y-dimensional and x-dimensional resonances can be observed from kilohertz to megahertz rates and can vary based on the length, width, and geometrical properties of cantilever 2600. Light that output from the tip of cantilever 2600 through cantilever waveguide 2614 can be projected in two-dimensional space by driving cantilever 2600 at these resonances while modulating the light. Cantilevers such as cantilever 2600 can therefore be used for 2D beam steering applications including (but not limited to) projecting a beam spot onto an atomic array of color centers (e.g., in a quantum computing system), performing 2D LiDAR scanning, and projecting an image in 2D space.

In some embodiments, two dimensional control of cantilever 2600 is accomplished by driving piezoelectric layer 2618 with an AC voltage v(t)=Aₓ sin(ωₓt+ϕₓ)+A_{y} sin(ω_{y}t+ϕ_{y}), where x denotes the direction parallel to the x-dimension (i.e., the width) of cantilever 2600 and y denotes the direction parallel to the y-dimension of cantilever 2600. While driving piezoelectric layer 2618, light that is input into waveguide 2614 may be modulated using an optical modulator 2626 (e.g., a shutter or an acousto-optic modulator). This control process can be used to perform a raster scan or to trace a Lissajous pattern. The phases ϕₓ, ϕ_{y} can be adjusted to change the shape of the Lissajous pattern. Synchronously modulating the input light with the pattern traced by the cantilever tip may display an image or allow a specific pattern to be traced.

Raster scanning can be accomplished via low-frequency, off-resonant signal scanning of one dimension e.g. the x-dimension of the cantilever and high-frequency, resonant signal scanning of another dimension e.g., the y-dimension cantilever. The light modulating signal may project scanlines. Lissajous scanning can be performed using dual resonances to simultaneously scan both the y-dimensional and x-dimensional cantilever axes.

The repetition rate may be the greatest common divisor between the y-dimensional resonance frequency and the x-dimensional resonance frequency. The refresh rate may be the speed (in Hz) at which a cantilever traces a pattern (e.g., projects an image) across a given imaging plane and returns to a starting x-directional and y-directional position. The refresh rate may depend on the ratio between the y-directional resonance frequency and the x-directional resonance frequency. For applications such as atomic color center excitation, a high repetition rate can be beneficial. For applications such as image projection and LiDAR scanning, a high fill rate may be more desirable.

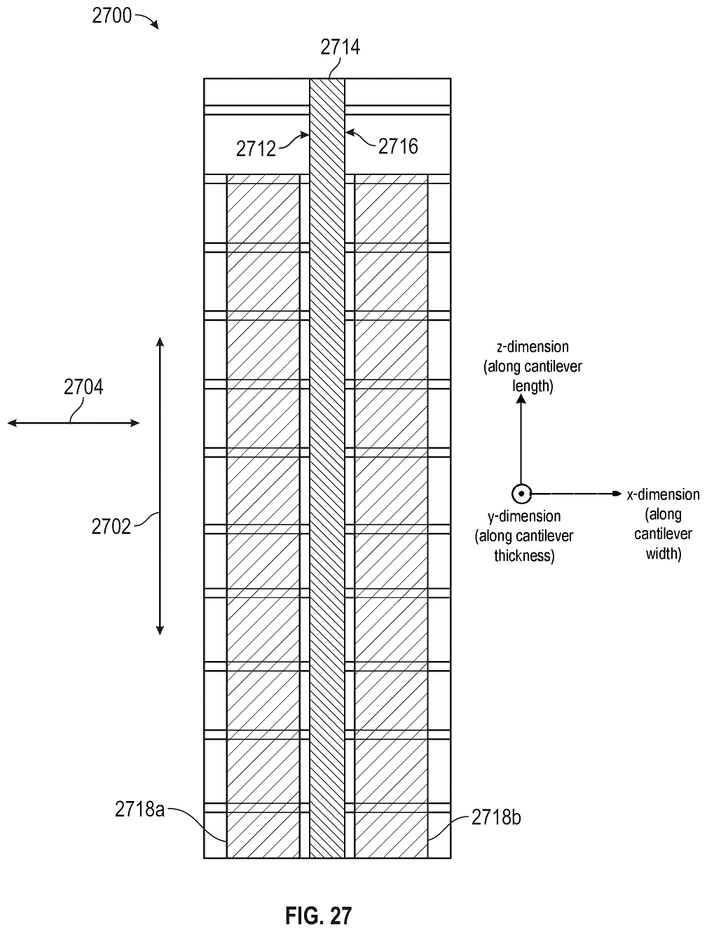

In some embodiments, a cantilever can comprise two independently controllable piezoelectric actuators, as illustrated in FIG. 27 where actuators 2718a and 2718b are split from one another in the x-dimension of the cantilever. As shown, a first piezoelectric actuator 2718a (e.g., a first piezoelectric segment) can be disposed in a first x-dimensional half of cantilever 2700 and a second piezoelectric actuator 2718b (e.g., a second piezoelectric segment) can be disposed in a second x-dimensional half of cantilever 2700. The first piezoelectric actuator 2718a of the cantilever 2700 may be disposed between a first dielectric layer (e.g., such as first dielectric layer 104 of cantilever 100 of FIG. 1) and a second dielectric layer (e.g., such as second dielectric layer 106 of cantilever 100 of FIG. 1) at a first position with respect to a first dimension parallel to the first dielectric layer of the cantilever 2700, such that the first dimension is dimension 2702. Similarly, the second piezoelectric actuator 2718b of the cantilever 2700 may be disposed between the first dielectric layer and the second dielectric layer at a second position with respect to the first dimension of the cantilever 2700, such that the first dimension is dimension 2702. The cantilever 2700 may include one or more waveguides, such as waveguide 2714, patterned in the second dielectric layer of the cantilever 2700. The waveguide 2714 may be any waveguide described herein, for instance waveguide 614 of FIGS. 6A-6B.

In some embodiments, the first piezoelectric actuator 2718a is disposed adjacent to a first side 2712 of the waveguide 2714 patterned in the second dielectric layer with respect to the dimension 2702 of the cantilever 2700. The second piezoelectric actuator 2718b may be disposed adjacent to a second side 2716 of the waveguide 2714 patterned in the second dielectric layer with respect to the dimension 2702 of the cantilever 2700.

In some embodiments, the cantilever 2700 includes a third independently controllable piezoelectric actuator (e.g., third piezoelectric segment) disposed between the first dielectric layer and the second dielectric layer. In some embodiments, the first piezoelectric actuator 2718a is disposed at the first position with respect to the dimension 2702 of the cantilever 2700, and the third piezoelectric actuator is disposed at a second position with respect to the dimension 2702 of the cantilever 2700. In some embodiments, the first piezoelectric actuator 2718a is disposed at the first position with respect to the dimension 2702, the second piezoelectric actuator 2718b is disposed at a second position with respect to the dimension 2702, and the third piezoelectric actuator is disposed at a third position with respect to the dimension 2702.

Generally, the cantilever may include any number of a plurality of piezoelectric actuators (e.g., 2, 3, 4, 5, 10, 20, 50, or more) that may or may not be offset from one another in the y-dimension, the x-dimension, both, or neither.

In some embodiments, the second dielectric layer includes a plurality of crossbars oriented at an angle relative to a length of the cantilever 2700 to control curvature in a x-dimension of the cantilever 2700. Such as described in reference to FIG. 2A and FIG. 2B, the second dielectric layer may comprise a patterning of crossbars (e.g., such as crossbars 210 of FIG. 2A) deposited on a surface (e.g., such as surface 212 of FIG. 2A) of the second dielectric layer. Each crossbar may have a length l_{c}, a width w_{c}, and a height h_{c} relative to the surface, and may be oriented at an angle θ_{c} relative to the length of the cantilever 2700. The patterning of the crossbars may be periodic along the length of the cantilever 2700. That is, the patterning of the crossbars may repeat after a given distance T along the length of the cantilever 2700, where T is the period of the crossbar patterning, such as the period T of the crossbar patterning described in reference to FIGS. 2A-2B.

In some embodiments, the cantilever 2700 includes a sacrificial layer that binds the cantilever 2700 to a substrate, such as described in reference to FIGS. 4A-4C. When the sacrificial layer is removed and the cantilever 2700 is released from the substrate, the cantilever 2700 may extend from an anchored portion (e.g., such as end 400a of FIGS. 4A-4C) in a direction parallel to the surface of the substrate. The deflection may be amplified due to a redirection of lateral strain along the longitudinal direction by the geometric patterning of the second dielectric layer. In some embodiments, the geometric patterning of the second dielectric layer causes the cantilever 2700 to deflect along its length in a direction away from the substrate (e.g., such as depicted in FIG. 4C). In some embodiments, the geometric patterning of the second dielectric layer causes the cantilever 2700 to deflect along its length in a direction toward the substrate. In some embodiments, part of the cantilever may deflect away from the substrate and another part of the cantilever may deflect toward the substrate.

Like cantilevers with a single actuator (e.g., cantilever 2600 shown in FIG. 26), when actuators 2718a-2718b are driven with AC voltages having certain frequencies, cantilever 2700 may demonstrate one or more y-dimensional resonances (at frequencies ω_{y}) and one or more x-dimensional resonances (at frequencies ωₓ). This may enable the waveguide tip of cantilever 2700 to be moved both x-directionally and y-directionally. The frequencies at which cantilever 2700 demonstrates the y-dimensional and x-dimensional resonances can be observed from kilohertz to megahertz rates and can vary based on the length, width, and geometrical properties of cantilever 2700. Light that output from the tip of cantilever 2700 through cantilever waveguide 2714 can be projected in two-dimensional space by driving cantilever 2700 at these resonances while modulating the light. Thus, like cantilever 2600, cantilever 2700 can be used for 2D beam steering applications including (but not limited to) projecting a beam spot onto an atomic array of color centers (e.g., in a quantum computing system), performing 2D LiDAR scanning, and projecting an image in 2D space.

In some embodiments, two dimensional control of cantilever 2700 is accomplished by driving piezoelectric actuator 2718a with an AC voltage v₁(t)=Aₓ sin(ωₓt+ϕₓ) and driving piezoelectric actuator 2718b with an AC voltage v₂(t)=A_{y} sin(ω_{y}t+ϕ_{y}) where x denotes the width of cantilever 2700 and y denotes the thickness of cantilever 2700. While driving actuators 2718a-2718b, light that is input into waveguide 2714 may be modulated using an optical modulator (e.g., a shutter or an acousto-optic modulator).

The y-dimensional frequency response of actuators 2718a-2718b may be in-phase due to the bending of cantilever 2700 that occurs in y-dimensional modes while the x-dimensional frequency response of actuators 2718a-2718b may be out of phase due to the twisting response of cantilever 2700 that occurs in x-dimensional modes. As a result, driving one of the actuators with an out of phase AC signal of the correct amplitude can fully cancel out the y-dimensional resonance while enhancing the x-dimensional resonance of cantilever 2700, thereby producing a straight horizontal line at the beam tip. For example, the y-dimensional resonance of cantilever 2700 can be canceled out by driving actuator 2718a with an AC voltage v₁(t)=Aₓ sin(ωₓt+ϕₓ) and driving actuator 2718b with an AC voltage v₂(t)=A_{y}A_{y_cancel} sin(ωₓt+ϕₓ+θ_{y_cancel}). An orthogonal response for 2D projection can be generated by driving actuator 2718a with an AC voltage v₁(t)=Aₓ sin(ωₓt+ϕₓ)+A_{y}A_{x_cancel} sin(ω_{y}t+ϕ_{y}+θ_{x_cancel}) and driving actuator 2718b with an AC voltage v₂(t)=AₓA_{y_cancel} sin(ωₓt+ϕₓ+θ_{y_cancel})+A_{y} sin(ω_{y}t+ϕ_{y}).

The resonant cancellation signals can be approximated with digital signals generated by a digital system such as an embedded processor, FPGA, phase locked loops, or voltage-controlled oscillators. An AND gate can be used between a first digital signal clock running at the x-dimensional resonance frequency ωₓ and a second digital signal clock running at the y-dimensional resonance frequency ω_{y} to generate a digital signal with dual frequency components.

In some embodiments, actuator 2718a and 2718b are configured to have similar or identical responses, in which case A_{y_cancel}≈1, θ_{y_cancel}≈π, A_{x_cancel}≈1, θ_{x_cancel}≈0.

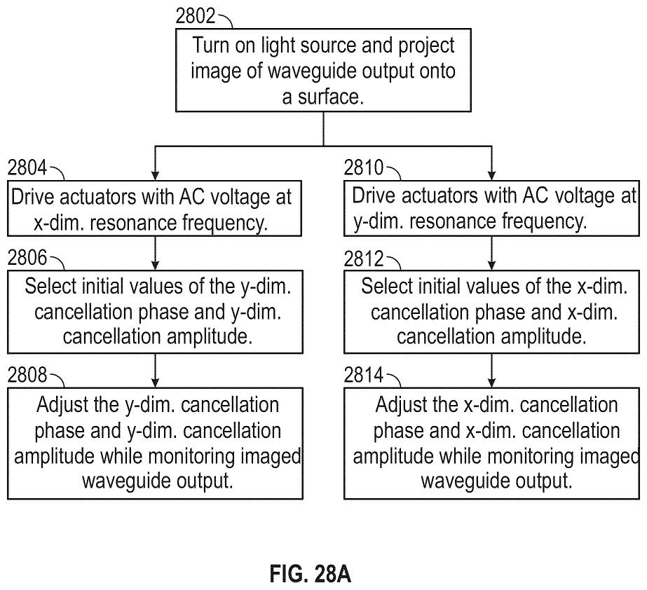

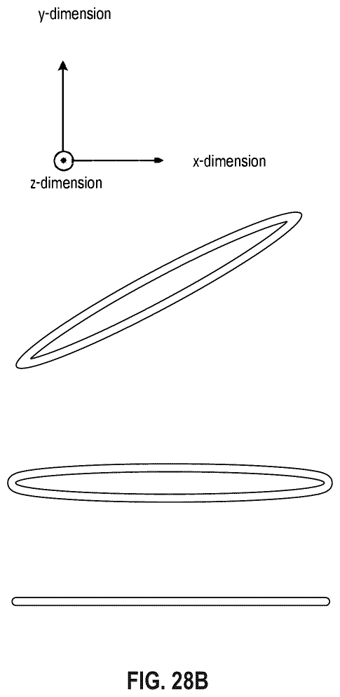

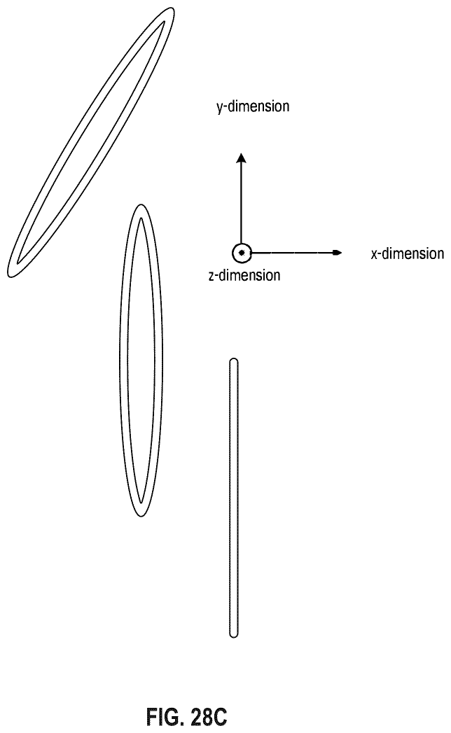

In some embodiments, the y-dimensional and x-dimensional resonances of a cantilever, such as cantilever 2700, can be calibrated and the cancellation amplitudes and phases can be determined using a calibration process. FIG. 28A illustrates an exemplary calibration process. First, a light source (e.g., a laser) that is optically coupled to provide light to the cantilever waveguide may be turned on and the output from the cantilever waveguide may be projected onto a surface (e.g., a wall) (step 2802). To calibrate the x-dimensional resonance, both actuators may be driven with AC voltages at the x-dimensional resonance frequency ωₓ (step 2804) with the x-dimensional amplitude Aₓ set to 1 and the y-dimensional amplitude A_{y} set to zero, which may cause the image of the waveguide output to appear as a (mostly x-directionally oriented) diagonal line or oval (see FIG. 28B). Initial values of the y-dimensional cancellation phase θ_{y_cancel} and the y-dimensional cancellation amplitude A_{y_cancel} may be selected (step 2806). In some embodiments, the initial value of the y-dimensional cancellation phase is set to π and the initial value of the y-dimensional cancellation amplitude is set to 1. The y-dimensional cancellation phase and the y-dimensional cancellation amplitude can then be adjusted while monitoring the imaged waveguide output (step 2808) until the image appears as a horizontal (that is, parallel to the x-dimension of the cantilever) line (FIG. 28B). To calibrate the y-dimensional resonance, both actuators may be driven with AC voltages at the y-dimensional resonance frequency ω_{y} (step 2810) with the x-dimensional amplitude Aₓ set to zero and the y-dimensional amplitude A_{y} set to 1, which may cause the image of the waveguide output to appear as a (mostly y-directionally oriented) diagonal line or oval (FIG. 28C). Initial values of the x-dimensional cancellation phase θ_{x_cancel} and the x-dimensional cancellation amplitude A_{x_cancel} may be selected (step 2812). In some embodiments, the initial value of the x-dimensional cancellation phase is set to 0 and the initial value of the x-dimensional cancellation amplitude is set to 1. The x-dimensional cancellation phase and the x-dimensional cancellation amplitude can then be adjusted while monitoring the imaged waveguide output (step 2814) until the image appears as a vertical line (FIG. 28C).

In some embodiments, the y-dimensional resonance of the cantilever, such as cantilever 2700, is suppressed and the x-dimensional resonance of the cantilever is enhanced by determining the y-dimensional cancellation amplitude and the y-dimensional cancellation phase using the workflow illustrated in FIG. 28A. In step 2802, a light source, that is configured to direct light into one or more waveguides of the cantilever, may be turned on. The output light output from the one or more waveguides of the cantilever may be projected onto an imaging plane (step 2802). In step 2804, a first voltage may be applied by one or more voltage sources to a first piezoelectric segment (e.g., such as actuator 2718a) to drive the first piezoelectric segment at the x-dimensional resonance frequency. A second voltage may be applied by the one or more voltage sources to a second piezoelectric segment (e.g., such as actuator 2718b) to drive the second piezoelectric segment at the x-dimensional resonance frequency. Driving the first piezoelectric segment at the first voltage and driving the second piezoelectric segment at the second voltage may induce oscillation of the cantilever 2700 at the x-dimensional resonance frequency and cause the output light to appear as a (mostly x-directionally oriented) diagonal line or oval (see FIG. 28B). Initial values of the y-dimensional cancellation phase θ_{y_cancel} and the y-dimensional cancellation amplitude A_{y_cancel} may be selected (step 2806), such that an initial amplitude of the first and second voltages is selected and an initial relative phase of the first and second voltages with respect to one another is selected. In some embodiments, the initial value of the y-dimensional cancellation phase is set to π and the initial value of the y-dimensional cancellation amplitude is set to 1. In step 2808, the one or more voltage sources may be controlled to modulate the amplitude of the first and second voltages to adjust the y-dimensional cancellation amplitude. The one or more voltage sources may also be controlled to modulate the relative phase of the first and second voltages with respect to one another to adjust the y-dimensional cancellation phase. The first and second voltages may be modulated while monitoring the output light, such that the first and second voltages may be modulated until the output light appears as a horizontal line (that is, parallel to the x-dimension of the cantilever) (FIG. 28B). As such, applying the first and second voltages with the determined y-dimensional cancellation amplitude and y-dimensional cancellation phase to the respective piezoelectric segments of the cantilever 2700 will suppress the y-dimensional resonance and enhance the x-dimensional resonance of the cantilever 2700.

In some embodiments, the x-dimensional resonance of the cantilever, such as cantilever 2700, is suppressed and the y-dimensional resonance of the cantilever is enhanced by determining the x-dimensional cancellation amplitude and the x-dimensional cancellation phase using the workflow illustrated in FIG. 28A. As before, in step 2802, the light source, that is configured to direct light into the one or more waveguides of the cantilever, may be turned on. The output light output from the one or more waveguides of the cantilever may be projected onto an imaging plane (step 2802). In step 2810, a first voltage may be applied by the one or more voltage sources to the first piezoelectric segment to drive the first piezoelectric segment at the y-dimensional resonance frequency. A second voltage may be applied by the one or more voltage sources to the second piezoelectric segment to drive the second piezoelectric segment at the y-dimensional resonance frequency. Driving the first piezoelectric segment at the first voltage and driving the second piezoelectric segment at the second voltage may induce oscillation of the cantilever 2700 at the y-dimensional resonance frequency and cause the output light to appear as a (mostly vertically oriented) diagonal line or oval (see FIG. 28C). Initial values of the x-dimensional cancellation phase θ_{x_cancel} and the x-dimensional cancellation amplitude A_{x_cancel} may be selected (step 2812), such that an initial amplitude of the first and second voltages is selected and an initial relative phase of the first and second voltages with respect to one another is selected. In some embodiments, the initial value of the x-dimensional cancellation phase is set to 0 and the initial value of the x-dimensional cancellation amplitude is set to 1. In step 2814, the one or more voltage sources may be controlled to modulate the amplitude of the first and second voltages to adjust the x-dimensional cancellation amplitude. The one or more voltage sources may also be controlled to modulate the relative phase of the first and second voltages with respect to one another to adjust the x-dimensional cancellation phase. The first and second voltages may be modulated while monitoring the output light, such that the first and second voltages may be modulated until the output light appears as a vertical line (that is, parallel to the y-dimension of the cantilever) (FIG. 28C). As such, applying the first and second voltages with the determined x-dimensional cancellation amplitude and x-dimensional cancellation phase to the respective piezoelectric segments of the cantilever 2700 will suppress the x-dimensional resonance and enhance the y-dimensional resonance of the cantilever 2700.

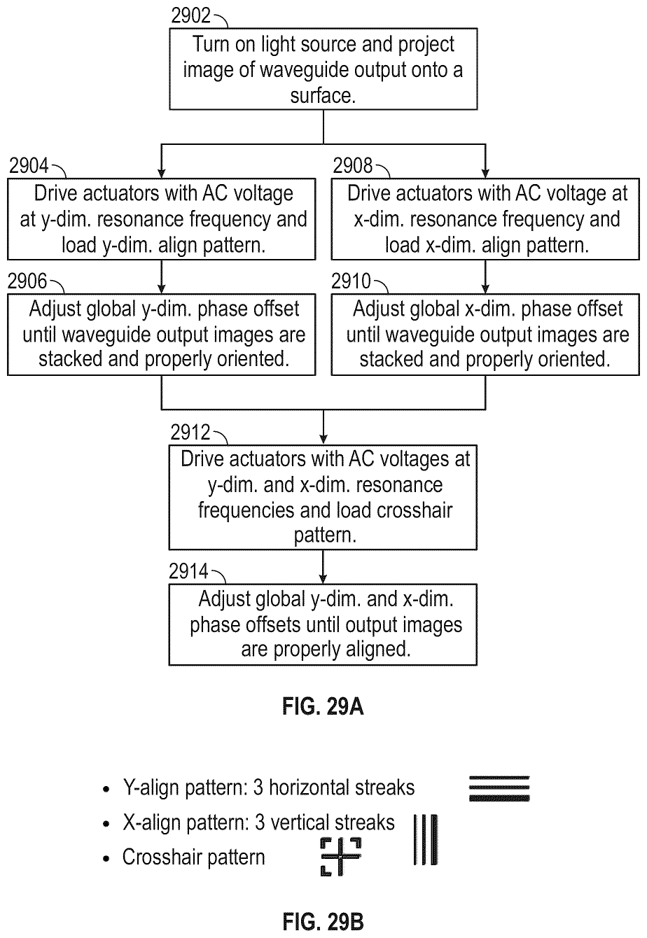

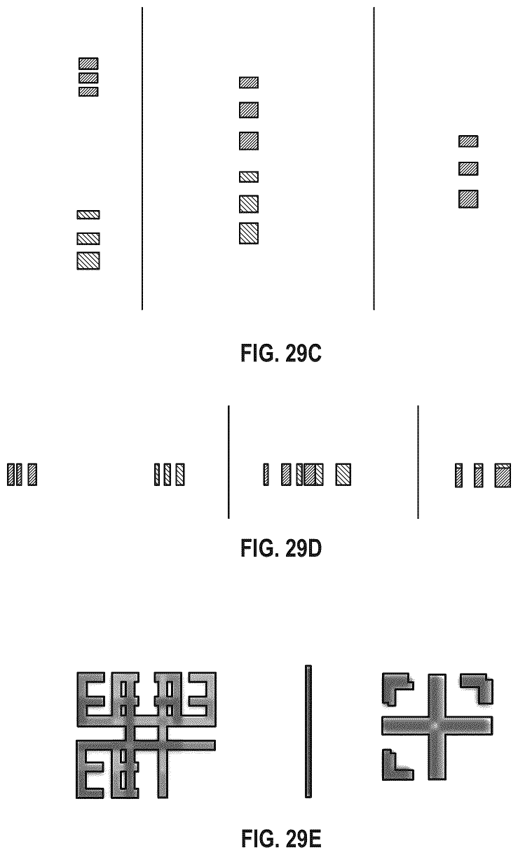

FIG. 29A shows an exemplary method for setting the global phase offsets ϕₓ and ϕ_{y} for image or point projection from a cantilever with split actuators such as cantilever 2700. First, a light source (e.g., a laser) that is optically coupled to provide light to the cantilever waveguide may be turned on and the output from the cantilever waveguide may be projected onto a surface (e.g., a wall) (step 2902). In some embodiments, the light provided to the cantilever waveguide is a light resulting from multiplexing light from a plurality of light sources. The light from each light source of the plurality of light sources may be a different wavelength (e.g., color). The actuators may be driven with an AC voltage at the y-dimensional resonance frequency ω_{y} with the x-dimensional amplitude Aₓ set to zero and the y-dimensional amplitude A_{y} set to 1, and a y-dimensional alignment pattern may be loaded (step 2904). The y-dimensional alignment pattern may comprise a plurality of horizontal lines of varying thicknesses (see, e.g., FIG. 29B). When the y-dimensional alignment pattern is loaded, two images of the y-dimensional alignment pattern may appear. Two images of the y-dimensional alignment pattern may appear because the oscillation (e.g., movement) of the cantilever induced by driving the actuators is such that the output from the cantilever waveguide during movement of the cantilever in a first direction (e.g., up/down or left/right) is not aligned with the output from the cantilever waveguide during movement of the cantilever in a second direction (e.g., left/right or up/down). The global y-dimensional phase offset ϕ_{y} may then be adjusted until the two images are on top of one another and properly oriented (step 2906; FIG. 29C). The actuators may then be driven with an AC voltage at the x-dimensional resonance frequency ωₓ with the x-dimensional amplitude Aₓ set to 1 and the y-dimensional amplitude A_{y} set to zero, and an x-dimensional alignment pattern may be loaded (step 2908). The x-dimensional alignment pattern may comprise a plurality of vertical lines of varying thicknesses (FIG. 29B). When the x-dimensional alignment pattern is loaded, two images of the x-dimensional alignment pattern may appear. The global x-dimensional phase offset ϕₓ may then be adjusted until the two images are on top of one another and properly oriented (step 2910; FIG. 29D).

After the y-dimensional and x-dimensional alignment patterns have been aligned, the actuators may be driven at both the x-dimensional and y-dimensional resonance frequencies, and a crosshair pattern may be loaded (step 2912; FIG. 29B). In some embodiments, a plurality of images of the crosshair pattern may appear because the oscillation (e.g., movement) of the cantilever induced by driving the actuators is such that the output from the cantilever waveguide during movement of the cantilever in a first direction (e.g., up/down or left/right) is not aligned with the output from the cantilever waveguide during movement of the cantilever in a second direction (e.g., left/right or up/down). The global x-dimensional phase offset and the global y-dimensional phase offset may be adjusted until the images of the crosshair pattern are aligned and properly oriented (step 2914; FIG. 29E).

For some optical applications (e.g., optical excitation of atomic color centers), a high repetition rate is more desirable than a high fill factor. To generate this, the ratio between the x-dimensional and y-dimensional resonant frequencies must be small. At ambient pressure, there may exist many suitable resonant frequency ratios for high-speed modulation.

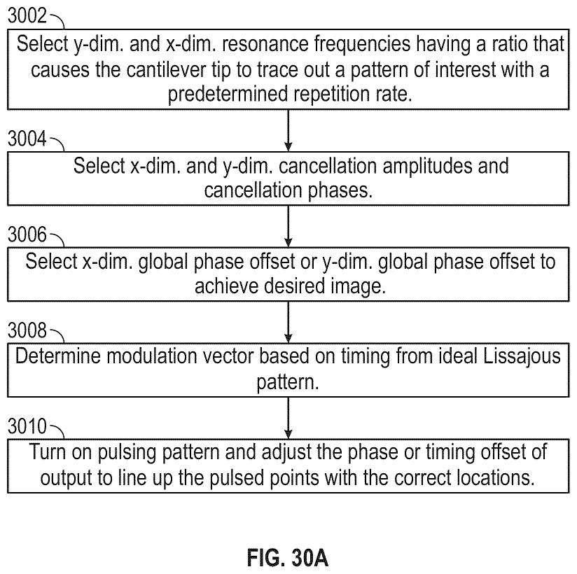

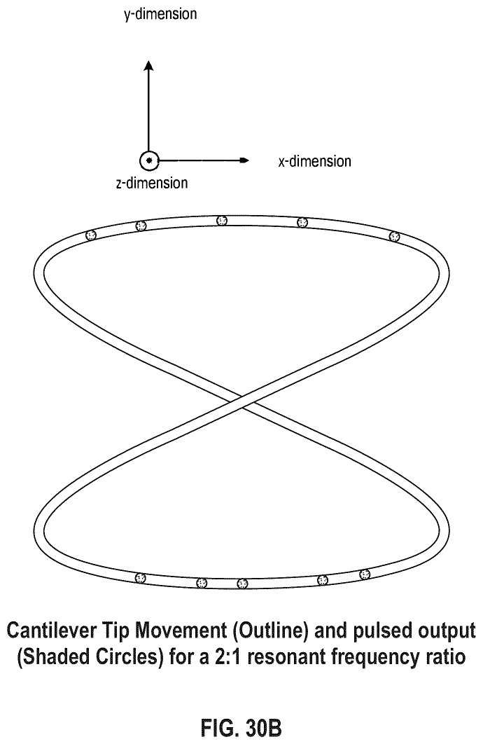

FIG. 30A provides an exemplary method for high-rate, low-fill projection using a cantilever with split actuators such as cantilever 2700. First, y-dimensional and x-dimensional resonance frequencies ωₓ, ω_{y} having a ratio that causes the cantilever tip to trace out a pattern of interest with a predetermined repetition rate may be selected (step 3002). The x-dimensional and y-dimensional cancellation amplitudes A_{x_cancel}, A_{y_cancel} and x-dimensional and y-dimensional cancellation phases θ_{x_cancel}, θ_{y_cancel} may then be selected (e.g., via a process such as the method shown in FIG. 28A) (step 3004). Subsequently, either the x-dimensional global phase offset Ør or the y-dimensional global phase offset Øy may be selected, e.g., using a process such as the method shown in FIG. 29A (step 3006). A modulation vector may be determined based on timing information associated with the ideal Lissajous pattern (step 3008). The pulsing pattern may then be turned on and the phase or timing offset of the light output may be adjusted to line up the pulsed points with the correct locations (e.g., as shown in FIG. 30B).

In some embodiments, the method illustrated in FIG. 30A may be used to generate a pulsing output from the one or more waveguides of the cantilever, such as the cantilever 2700, wherein the pulses are temporally spaced from one another and are accordingly spatially spaced from one another in a target plane as the cantilever moves in a Lissajous pattern during the pulsing. In step 3002, a y-dimensional resonance frequency of the cantilever and a x-dimensional resonance frequency of the cantilever may be selected such that a ratio of y-dimensional and x-dimensional resonance frequencies is in accordance with the Lissajous pattern. For instance, as described above, the y-dimensional and x-dimensional resonance frequencies may be selected such that the ratio causes the cantilever tip to trace the Lissajous pattern with a predetermined repetition rate. For instance, a first voltage may be applied to a first actuator (e.g., such as actuator 2718a of cantilever 2700) of the cantilever and a second voltage may be applied to a second actuator (e.g., such as actuator 2718b of cantilever 2700) of the cantilever. The first voltage and the second voltage may be applied at the selected y-dimensional and x-dimensional resonance frequencies such that the cantilever tip traces the Lissajous pattern. In step 3004, the x-dimensional cancellation phase and/or the y-dimensional cancellation phase may be determined, for instance, via the method of FIG. 28A (e.g., by adjusting the y-dimensional cancellation phase in accordance with monitoring the waveguide output position). The x-dimensional cancellation amplitude and/or the y-dimensional cancellation amplitude may also be determined, for instance, via the method of FIG. 28A (e.g., by adjusting the x-dimensional cancellation phase in accordance with monitoring the waveguide output position). The x-dimensional cancellation amplitude, the x-dimensional cancellation phase, the y-dimensional cancellation amplitude, and/or the y-dimensional cancellation phase may be determined (including, in some embodiments, by monitoring waveguide output position and adjusting voltage parameters accordingly) such that the cantilever tip traces the Lissajous pattern, such as the Lissajous pattern illustrated in FIG. 30B. For instance, as described above, the first voltage and the second voltage applied to the first actuator and the second actuator, respectively, may be generated in accordance with the determined x-dimensional cancellation amplitude, the determined x-dimensional cancellation phase, the determined y-dimensional cancellation amplitude, and/or the determined y-dimensional cancellation phase. As such, applying this first voltage and second voltage may cause the cantilever to trace out the Lissajous pattern.

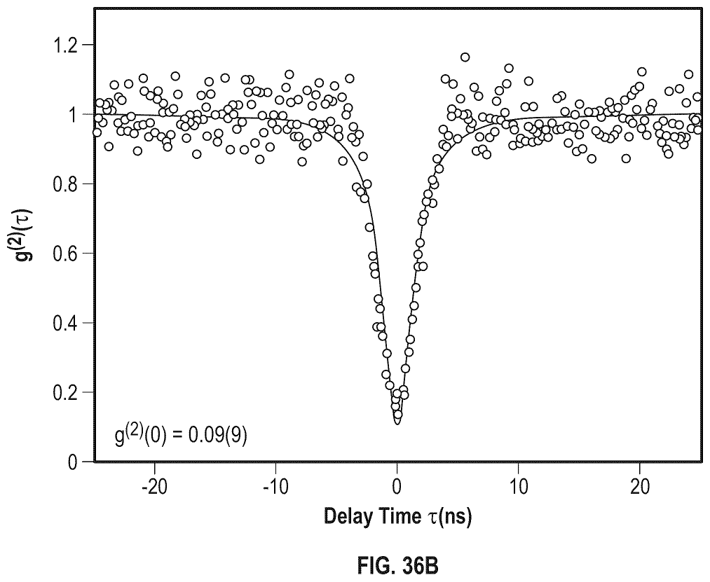

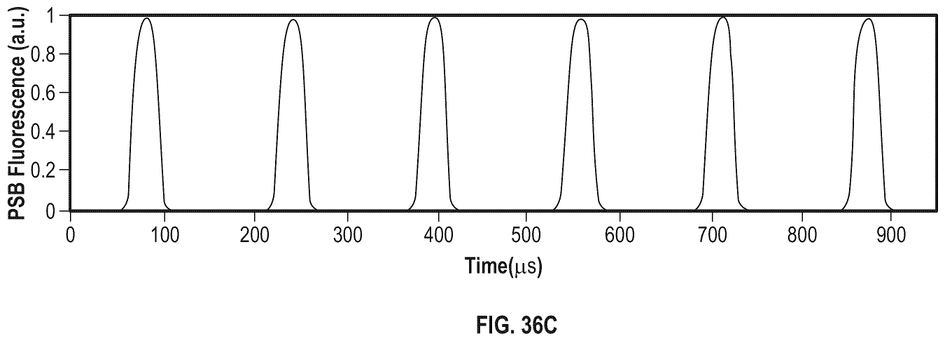

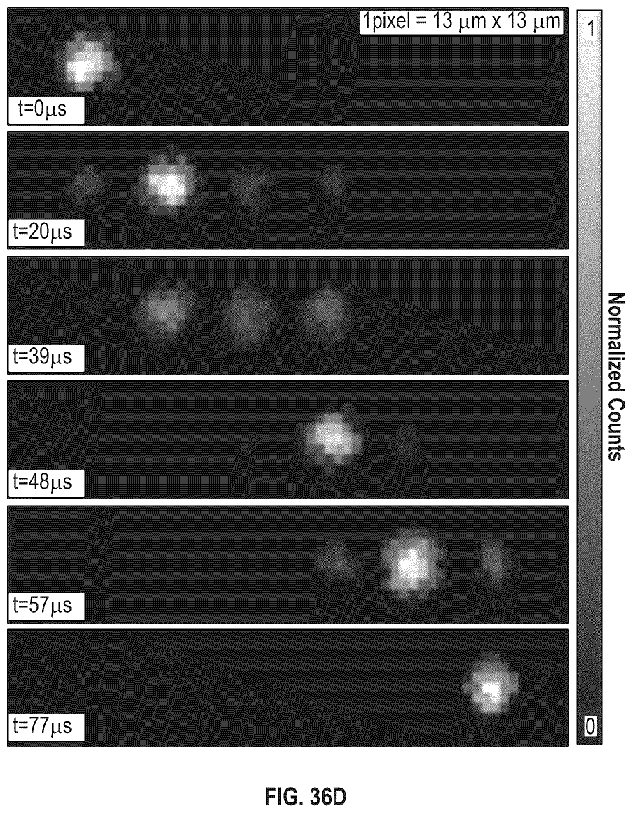

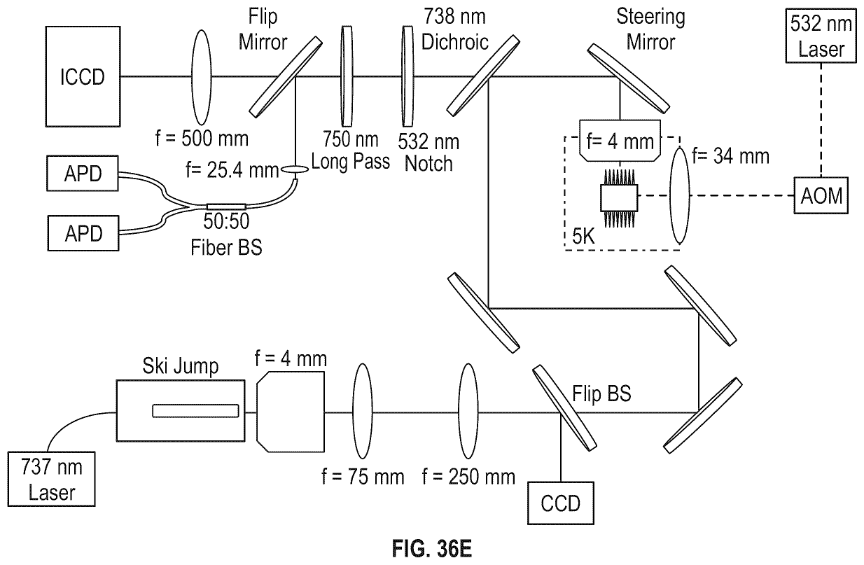

In step 3006, a x-dimensional global phase offset ϕₓ and/or a y-dimensional global phase offset ϕ_{y} may be determined, for instance, via the method of FIG. 29A (e.g., by adjusting the x-dimensional global phase offset in accordance with monitoring the waveguide output position). The x-dimensional global phase offset and/or the y-dimensional global phase offset may be determined such that the cantilever tip traces out the Lissajous pattern (e.g., applying the first and second voltage, such that the first and second voltage are generated in accordance with the x-dimensional global phase offset and/or the y-dimensional global phase offset). In step 3008, a modulation vector may be determined based on timing information associated with the desired Lissajous pattern. For instance, the modulation vector may be determined based on temporal and spatial spacing between pulses of light, such that when the pulsed light is applied to the one or more waveguides of the cantilever, a pulsed output is projected from the one or more waveguides while the cantilever tip traces the desired Lissajous pattern (see FIG. 30B). In step 3010, pulsed light may be applied to the one or more waveguides of the cantilever using a light source, such as described in reference to FIG. 28A, to produce the pulsed output as the cantilever tip traces the Lissajous pattern, such as the pulsed output of FIG. 30B. In some embodiments, at least one parameter of the pulsed light is adjusted to tune the pulsed output from the one or more waveguides as the cantilever tip traces the Lissajous pattern. For instance, the time between pulses or the start time of the pulses may be adjusted to tune the temporal and spatial spacing between the pulses. In some embodiments, the pulsed output is used to operate and monitor color centers of a quantum diamond microchiplet, such as described in reference to FIG. 36A.

The mechanical quality factor and resonant enhancement factor of a cantilever such as cantilever 2600 or cantilever 2700 can be tuned by changing the pressure applied to the cantilever. For example, since air molecules can mechanically damp a cantilever, vacuum-sealing the cantilever can increase the resonant enhancement and quality factors, enabling at-resonance driving with lower voltages and creating a narrow resonant frequency bandwidth.

In some embodiments, a narrow resonant frequency bandwidth is not desired. For example, in order to move the cantilever tip in a quicky repeating oval or circle (e.g., in order to project an image of an oval or a circle), the frequency may need be such that the cantilever resonates to move the tip both horizontally and vertically. Increasing the pressure applied to the cantilever may lower the quality factor and widen the bandwidth, thereby allowing the appropriate frequency to be easily identified.

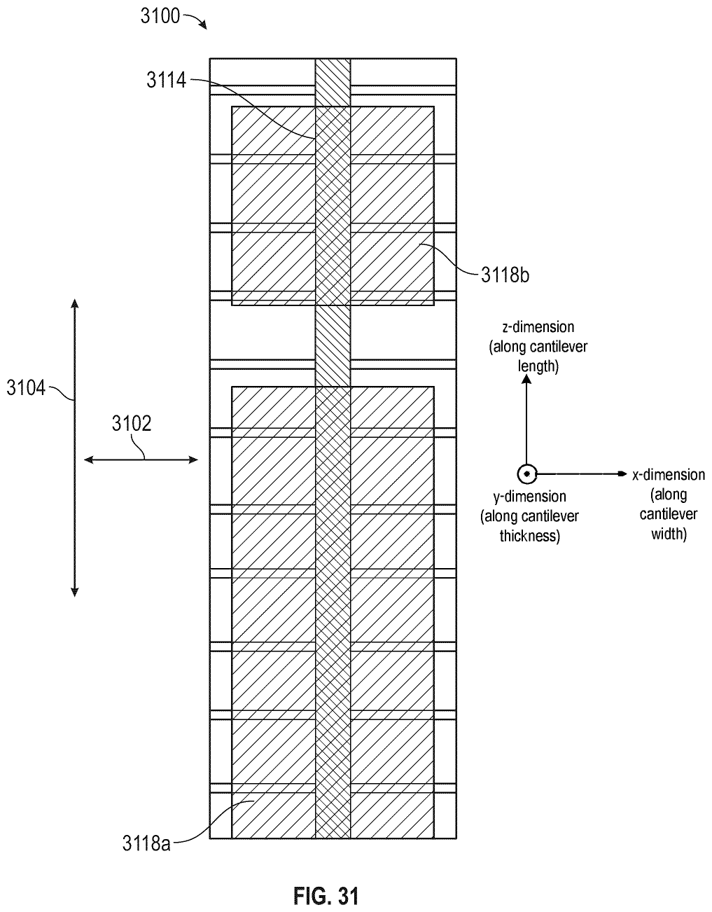

In some embodiments, a cantilever can comprise two independently controllable piezoelectric actuators, as shown in FIG. 31 in an exemplary z-dimensionally-split arrangement. As shown, a first piezoelectric actuator 3118a can be disposed in a first z-dimensional half of cantilever 3100 along axis 3104 and a second piezoelectric actuator 3118a can be disposed in a second z-dimensional half of cantilever 3100. The actuators may be located in a same or overlapping position along x-directional axis 3102. The cantilever 3100 may include one or more waveguides, such as waveguide 3114, patterned in the second dielectric layer of the cantilever 3100. The waveguide 3114 may be any waveguide described herein, for instance waveguide 614 of FIGS. 6A-6B.

In some embodiments, the cantilever 3100 includes a third independently controllable piezoelectric actuator (e.g., third piezoelectric segment) disposed between the first dielectric layer and the second dielectric layer. A first, second, and third piezoelectric actuator may be offset from one another in the x-dimension and/or the z-dimension of the cantilever.

In some embodiments, the second dielectric layer includes a plurality of crossbars oriented at an angle relative to a length of the cantilever 3100 to control curvature in a x-dimension of the cantilever 3100. Such as described in reference to FIG. 2A and FIG. 2B, the second dielectric layer may comprise a patterning of crossbars (e.g., such as crossbars 210 of FIG. 2A) deposited on a surface (e.g., such as surface 212 of FIG. 2A) of the second dielectric layer. Each crossbar may have a length l_{c}, a width w_{c}, and a height h_{c} relative to the surface, and may be oriented at an angle θ, relative to the length of the cantilever 3100. The patterning of the crossbars may be periodic along the length of the cantilever 3100. That is, the patterning of the crossbars may repeat after a given distance T along the length of the cantilever 3100, where T is the period of the crossbar patterning, such as the period T of the crossbar patterning described in reference to FIGS. 2A-2B.

In some embodiments, the cantilever 3100 includes a sacrificial layer that binds the cantilever 3100 to a substrate, such as described in reference to FIGS. 4A-4C. When the sacrificial layer is removed and the cantilever 3100 is released from the substrate, the cantilever 3100 may extend from an anchored portion (e.g., such as end 400a of FIGS. 4A-4C) in a direction parallel to the surface of the substrate. The deflection may be amplified due to a redirection of lateral strain along the longitudinal direction by the geometric patterning of the second dielectric layer. In some embodiments, the geometric patterning of the second dielectric layer causes the cantilever 3100 to deflect along its length in a direction away from the substrate (e.g., such as depicted in FIG. 4C). In other embodiments, the geometric patterning of the second dielectric layer causes the cantilever 3100 to deflect along its length in a direction toward the substrate.

Cantilever 3100 can provide increased enhancement and control of the resonant modes and may have a mechanical node at a point between actuators 3118a-3118b when actuator 3118a and actuator 3118b are driven with out of phase signals. Cantilever 3100 can also enable broad angle tuning by driving cantilever 3118a with a DC voltage and driving cantilever 3118b with a high-speed resonant voltage. Resonantly driving cantilever 3118b may create a large change in the angle of the cantilever tip but a small change in the height of the beam, which may result in less defocusing that a single-actuator cantilever. In some embodiments, a x-dimensional cancellation amplitude, a x-dimensional cancellation phase, a y-dimensional cancellation amplitude, and/or a y-dimensional cancellation phase may be determined using the method of FIG. 28A. In some embodiments, a x-dimensional global phase offset and/or a y-dimensional global phase offset may be determined using the method of FIG. 29A. In some embodiments, a pulsed output from the one or more waveguides of the cantilever 3100 may be generated as the cantilever 3100 moves in accordance with a Lissajous pattern (e.g., such as using the method of FIG. 30A).

### Example 16: Large Curvature Photonic Cantilever Device

This example describes and provides applications of a piezoelectrically actuated, large curvature photonic cantilever device.

### Device Overview

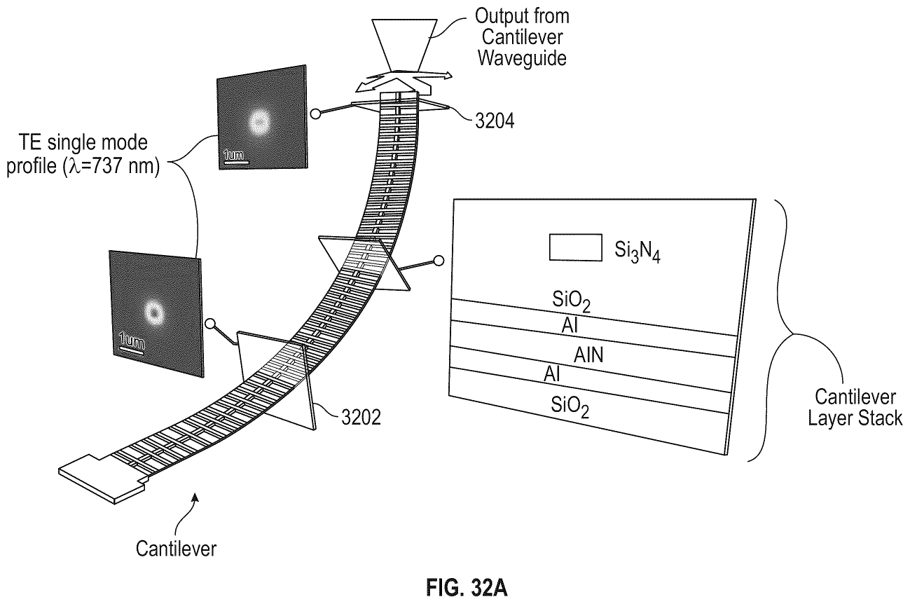

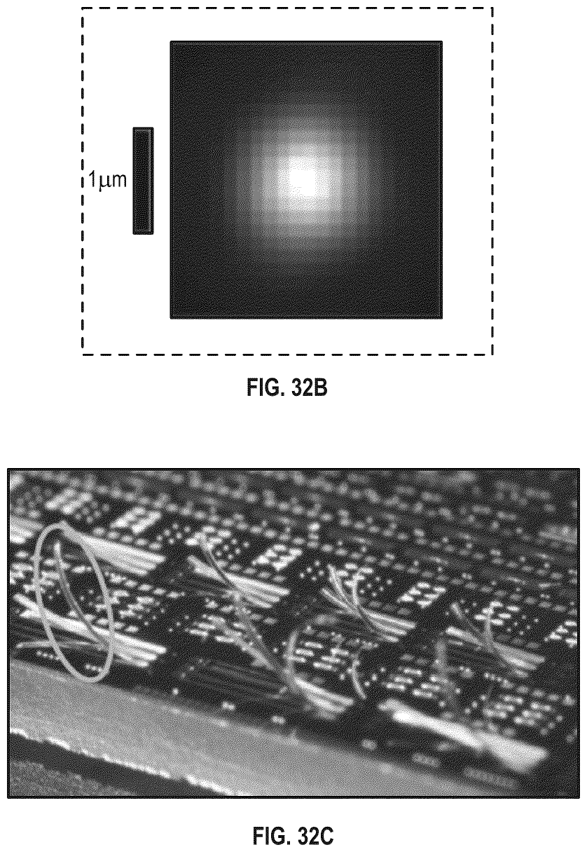

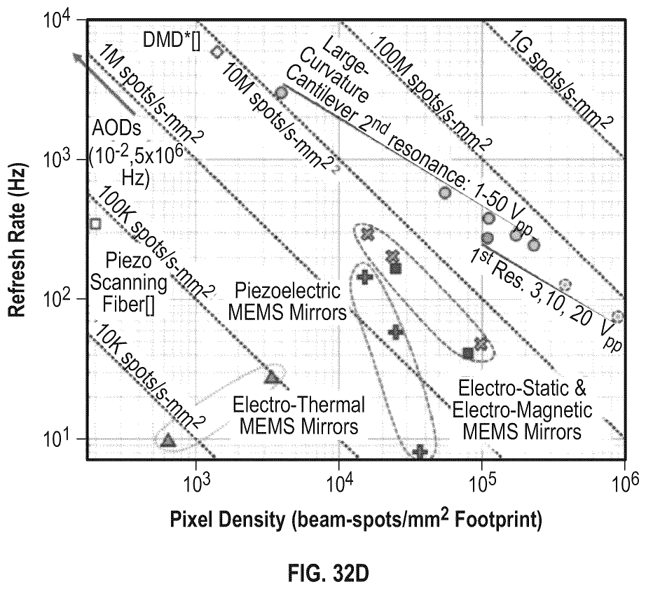

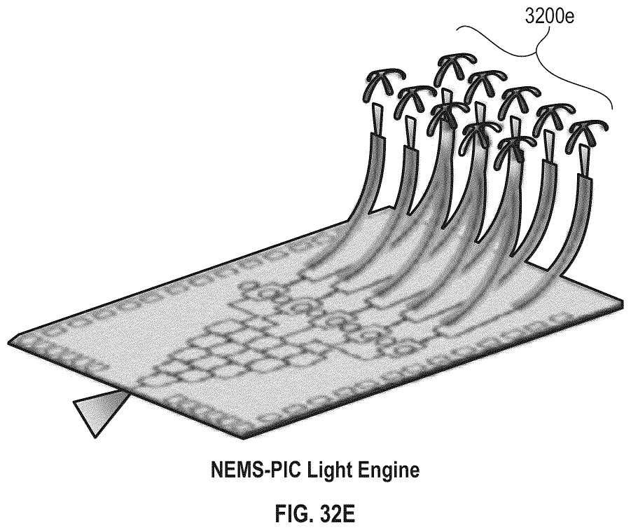

Cantilevers were fabricated using a 200 mm CMOS foundry process and includes (as shown in FIG. 32A) the following layers: a sacrificial amorphous silicon layer that binds the cantilever to an underlying substrate, a first dielectric layer comprising silicon dioxide, a first aluminum electrode, a piezoelectric layer comprising aluminum nitride, a second aluminum electrode, a second dielectric layer comprising silicon dioxide. Patterned within the second dielectric layer is a silicon nitride waveguide channel.

The silicon dioxide, aluminum nitride, and silicon nitride each have different initial stress values based on deposition parameters that, when the sacrificial layer is removed to release the cantilever from the underlying substrate, cause the cantilever to curl upwards. A DC or AC voltage can be applied across the aluminum electrodes of the cantilever to drive the piezo-actuation of the aluminum nitride layer. The actuation of the aluminum nitride layer in turn drives the cantilever back and forth to allow beam steering.

The dimensions of the waveguide channel in the cantilever can be tailored for broadband visible wavelength single mode TE or TM light. FIG. 32A shows the TE single mode profile along the length of the waveguide for light with a wavelength λ of 737 nm. In some embodiments, the dimensions of one or more waveguides of a cantilever (e.g., such as cantilever 2700 or 3100) may be configured (e.g., such as tapered along the length of the one or more waveguides) to adjust the TE single mode profile size. For instance, the one or more waveguides may be configured such that the TE single mode profile size at a first position 3202 of the cantilever is different than the TE single mode profile size at a second position 3204 of the cantilever. In some embodiments, the TE single mode profile size is enlarged relative to the first position 3202 to increase a coupling efficiency of the output light from the one or more waveguides. In some embodiments, the TE single mode profile size is adjusted in accordance with an optical output from color centers of a quantum microchiplet, such as described in reference to FIG. 36A.

Output from the end of the waveguide channel as magnified onto an ICCD camera is shown in FIG. 32B. FIG. 32C shows a photograph of several different cantilevers having the layer stack shown in FIG. 32A on a photonic integrated circuit (PIC). Some of these cantilevers (e.g., the cantilever circled in FIG. 32C) achieve upward curling of at least 90 degrees.

FIG. 32D shows beam scan speed data for different types of 2D laser beam scanners, including the large-curvature cantilever depicted in FIG. 32A. The scan speed was compared by calculating refresh rate and density of resolvable spots for each type of beam scanner. The large-curvature cantilever achieved a scan speed near the top of the field (e.g., an order of magnitude more beam spots/s*mm² than other beam scanners).

FIG. 32E shows an example PIC with multiple large-curvature cantilevers 3200e. This PIC may allow for independent scanning of multiple different beams and wavelengths for applications such as image projection, LiDAR, and qubit control. The cantilever devices can be integrated into the PIC along with other optical devices such as (but not limited to) (i) a strain Mach-Zehnder interferometer (MZI), (ii) a cantilever MZI, (iii) ring resonators, (iv) strain cantilevers, (v) a programmable multimode interferometer mesh, (vi) tunable directional couplers, and (vii) strain-tunable photonic crystal cavities. As shown in FIG. 32E, input light into a chip can pass through numerous devices for performing on-chip operations before the output is driven via the cantilever array. In some embodiments, the PIC with the multiple large-curvature cantilevers 3200e includes one or more light sources (e.g., on-chip lasers) configured to generate light that is applied to the multiple large-curvature cantilevers.

### Characterization of Cantilever Devices Based on Geometric Parameter Variations and DC Actuation

Cantilevers having the layer stack shown in FIG. 32A were designed with varying length (L), width (W), number of silicon nitride waveguides (wgn), and waveguide pitch (wgp). The cantilevers were also fabricated with the top oxide layer entirely removed except for a protective buffer around the silicon nitride waveguide (“pad-open etch”) as well as with a crossbar pattern (p=crossbar period, e=etch duty cycle) that controls the level of curl-up of the cantilever.

The bottom oxide layer was estimated to be moderately compressive. The stress in the aluminum nitride was estimated to change, from bottom to top, from moderately compressive to moderately tensile. The top oxide layer was estimated to be moderately compressive. The silicon nitride waveguide was estimated to be highly compressive. The thin aluminum electrode layers that sandwich the aluminum nitride have minimal inherent stress. As such, released cantilevers containing just bottom oxide and the aluminum-aluminum nitride-aluminum stack curled upward due to the combination of underlying compressive and overlaying tensile stresses. The stresses are linear, so longer and wider cantilevers will curl up to a larger final angle. Because the silicon nitride deposited is highly compressive, depositing one or more silicon nitride waveguides on top pushed the cantilever back downward.

Cantilevers which have a pad-open etch were less uniform in their curling behavior and curled up out of plane less than 30 degrees without a silicon nitride waveguide and even less with a silicon nitride waveguide. Cantilevers with lengths L=1400 μm patterned with oxide crossbars (wgp=2 μm, e=50%) and having no waveguide often curled more than 90 degrees upward; some curled up to 270 degrees. As width increased, the curl generally increased for a given sample. Shorter cantilevers of length 800 μm with oxide crossbars and no waveguide frequently curled past 90 degrees when 50 μm or wider. Similar cantilevers that included waveguides curled up less, though several designs curled up to or past 90 degrees. On average, cantilevers with 150 nm thick silicon nitride waveguides curled up more than cantilevers having the same geometry with a 300 nm thick silicon nitride waveguides.

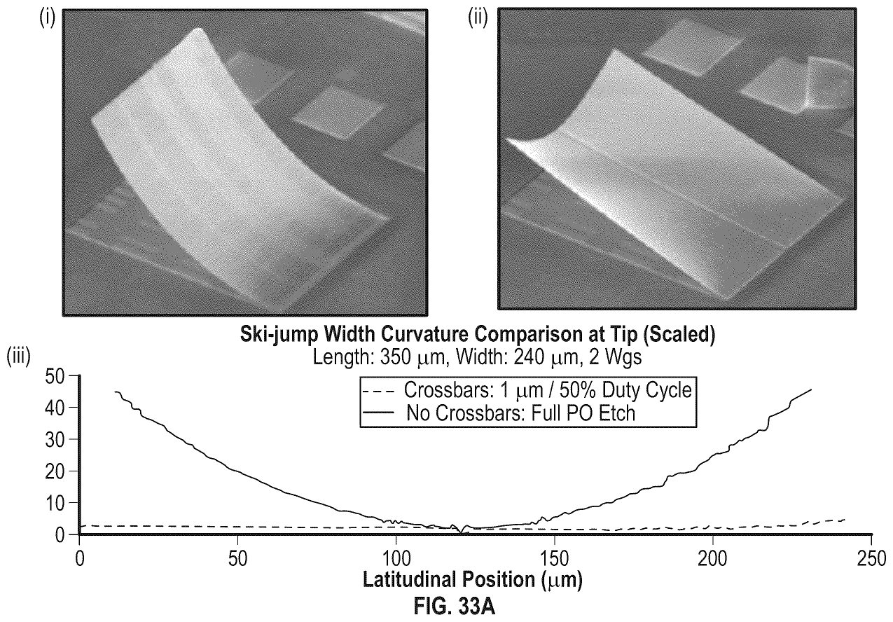

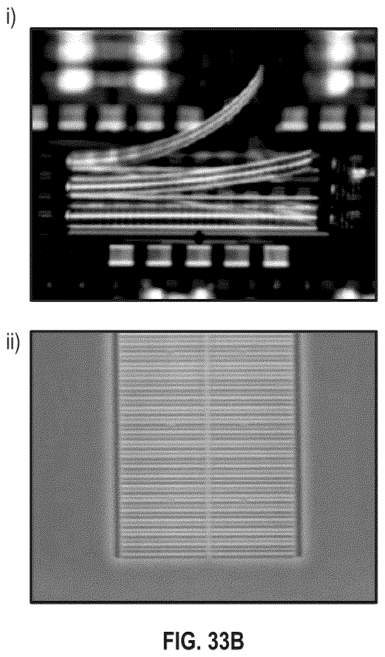

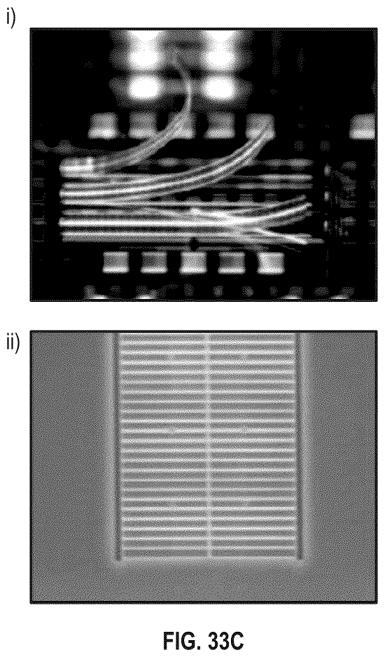

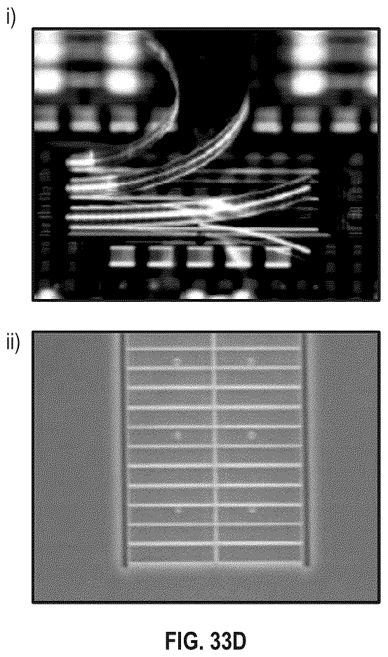

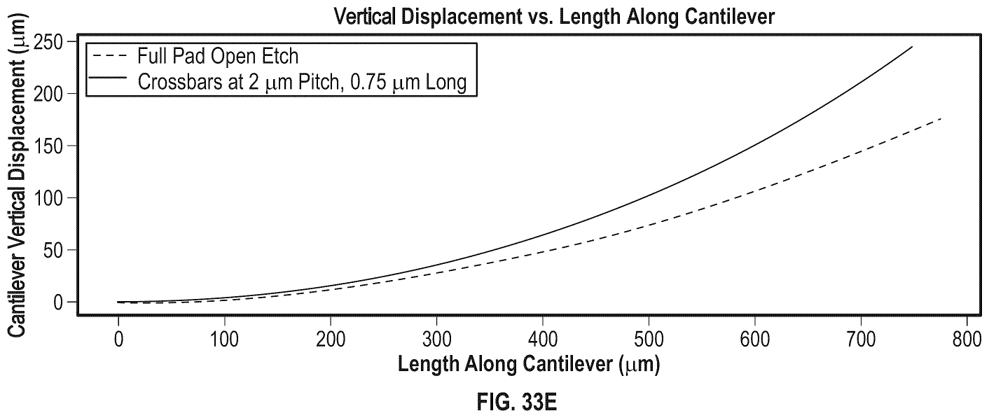

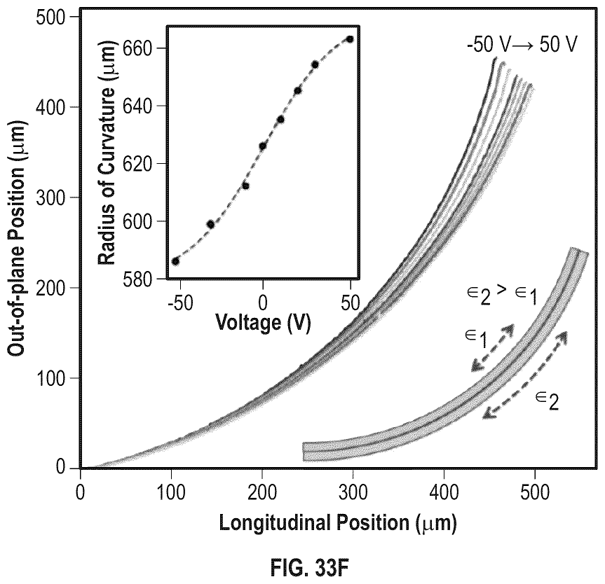

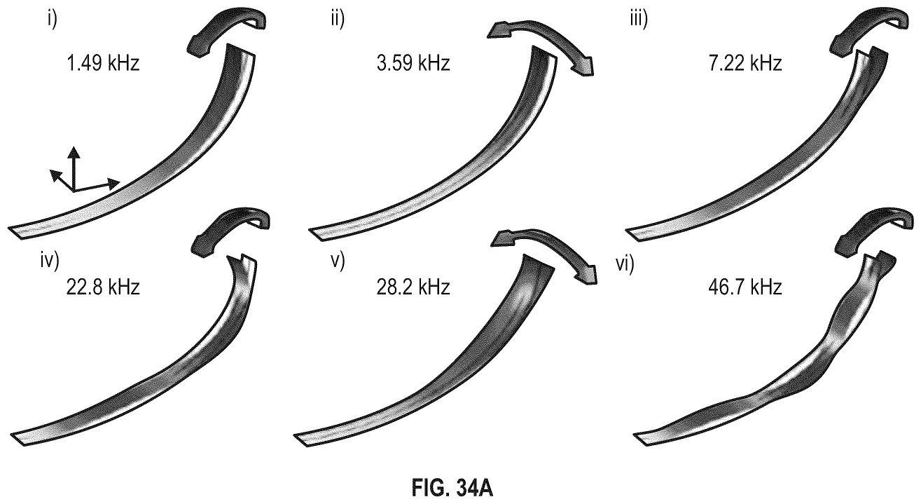

FIG. 33A shows the effect of the top oxide layer and the crossbar patterning on cantilever curvature. Cantilevers with a width W=240 μm and a length L=350 μm were fabricated with the top oxide entirely removed except for a protective buffer around the waveguide channel (“pad open etch”, shown in FIG. 33A (ii)) and with 1 μm crossbars at a 2 μm pitch (shown in FIG. 33A (i)). For the pad open etch design, the stresses in the cantilever following its release are not optimally channeled and cause lateral curling due to the concentrated compressive stress of the single silicon nitride waveguide. With the oxide crossbars, the cantilever curls up far more uniformly and with a higher angle. The oxide patterning provides a “back bone” to the cantilever that suppresses lateral curling and enhances longitudinal curling while simultaneously increasing and making more uniform the bending moment of all of the cantilever layers (FIG. 33A (iii)).

FIGS. 33B-33D shows the effects of varying cantilever width, waveguide number, and crossbar duty cycle. Cantilevers with a length L=950 μm were fabricated with varying widths (W=70, 90, and 110 μm), varying waveguide number (wgn=1, 2, and 4, spaced 3 μm apart along the middle of the cantilever). The cantilevers were patterned with 1 μm length crossbars (with the crossbar length running in the z-direction along the length of the cantilever) with varying pitch (p=2 μm, 4 μm, and 8 μm). Because the silicon dioxide is moderately compressive, while the crossbars redirected lateral stresses, they still pushed down the cantilever somewhat. Decreasing the effective amount of top oxide while keeping a sufficient number of crossbars to prevent lateral curling therefore allowed the cantilever to curl up more. FIG. 33B (i) illustrates the cantilevers with the length L=950 μm with the varying widths (W=70, 90, and 110 μm) and the varying waveguide number (wgn=1, 2, and 4) for the pitch p=2 μm. FIG. 33B (ii) illustrates a crossbar spacing associated with the pitch p=2 μm. FIG. 33C (i) illustrates the cantilevers with the length L=950 μm with the varying widths (W=70, 90, and 110 μm) and the varying waveguide number (wgn=1, 2, and 4) for the pitch p=4 μm. FIG. 33C (ii) illustrates a crossbar spacing associated with the pitch p=4 μm. FIG. 33D (i) illustrates the cantilevers with the length L=950 μm with the varying widths (W=70, 90, and 110 μm) and the varying waveguide number (wgn=1, 2, and 4) for the pitch p=8 μm. FIG. 33D (ii) illustrates a crossbar spacing associated with the pitch p=8 μm.

FIG. 33E shows data from a COMSOL finite element modeling simulation of cantilevers with a length L=800 μm and a width W=70 μm. FIG. 33E illustrates a simulated cantilever with the pad open etch configuration (e.g., a cantilever without crossbars) and a simulated cantilever with the 2 μm pitch, 1 μm etch (50% duty cycle) of crossbars. The simulated cantilever with the crossbars displayed more curling than the cantilever with the pad open etch configuration.

The piezo-electric behavior of the aluminum nitride layer allows for moving the output of the embedded waveguide at DC voltages and AC drive frequencies. DC voltage biasing from −50 V to 50 V was applied to cantilevers of a length L=800 μm and a width W=50 μm and the curling of the cantilevers was measured on a white light profilometer (FIG. 33F). DC tuning allows fine control of the output of the device for more precise alignment of the output of the device to couple to free space optics or potential optical fibers.

### Characterization of Mechanically Resonant Modes of Cantilever Devices

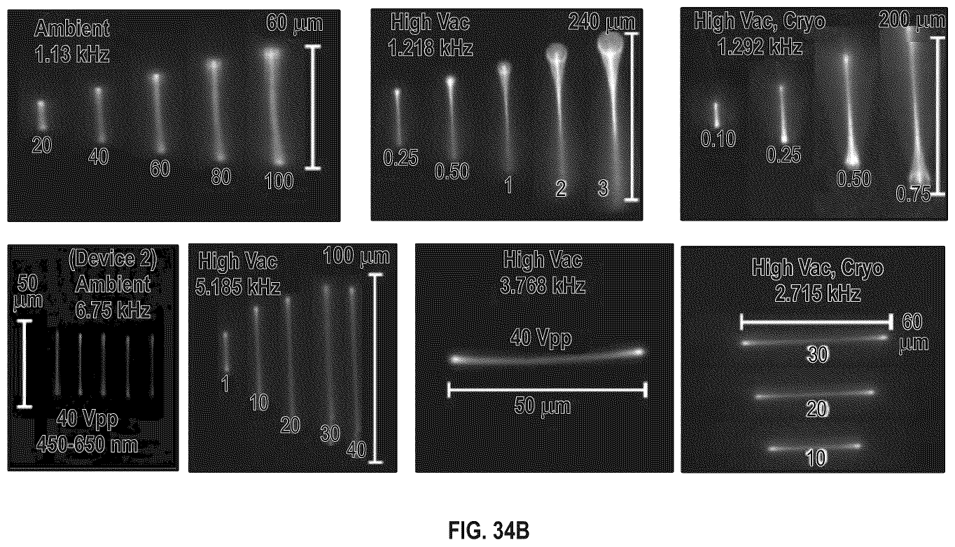

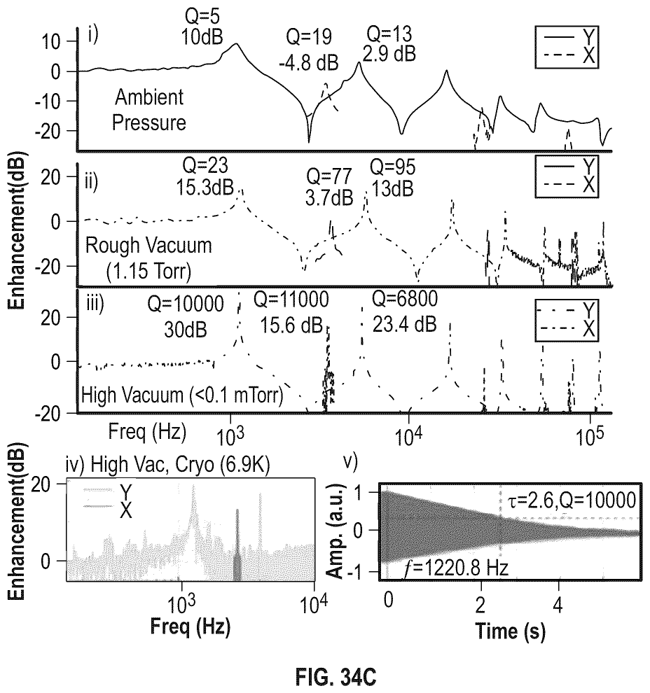

The cantilever devices displayed an array of mechanical resonances that enhance the bending of the cantilever and the overall scanning range. The resonant frequencies and mode shapes depend on the device geometry, with width and length having the most significant impact. COMSOL Finite Element Method simulations were used to calculate the mechanical eigenmodes of a cantilever curled to 90 degrees with dimensions L=800 μm, W=70 μm, WG-300×400 nm (e.g., dimensions of a waveguide of the cantilever), without crossbars. The eigenmodes are shown in FIG. 34A. Resonances were observed that enhanced the waveguide tip displacement on both the y-dimensional and the x-dimensional axes. The first eigenmode exhibited deviation in the vertical direction the further from the equilibrium point the device is driven. In comparison, the second eigenmode exhibited high quality horizontal motion over a range of ˜50 μm with limited deflection in the vertical direction. As such, the second eigenmode can be used for high-speed beam steering.

The AC response of a cantilever device (dimensions L=950 μm, W=70 μm, WG=300×400 nm, cp=2 μm, e=50%) was characterized at varying pressures and cryogenic temperatures by: 1) placing it in a cryostat, 2) using optical fiber feedthroughs to edge couple to an on-chip waveguide, and 3) collecting the device output through the cryostat glass window into a 50× long working distance objective. The light was then routed to a CMOS Imaging Camera, a high-speed Intensified Charge Coupled Device (ICCD), or a position sensitive photodetector. The cantilever was driven using an arbitrary waveform generator, optionally connected to an amplifier to drive up to 100 Vpp.

FIG. 34B shows beam streaks from long exposure ICCD imaging at the first few resonances. As expected, the device exhibited y-dimensional and x-dimensional resonances. The trajectory of the cantilever tip in the Y-Z and X-Z planes, respectively, is dictated by the shape of the resonance modes, which are qualitatively similar to those of uncurled cantilevers. The first Y-resonance, despite its large passive curvature, moves along a nearly-circular path in the Y-Z plane, similar to conventional fiber scanners. The second resonance, with a single node and odd-symmetry, provides a smaller but flatter scan path. At high vacuum (<0.1 mTorr), similar displacements were measured with over 100 times lower drive voltage compared to ambient for the first Y-resonance. The device may be vacuum encapsulated and driven at CMOS voltages under these conditions.

Time-gated measurements were performed to further confirm the high-speed motion of the device and verify that it is moving at the drive frequencies for the first and second order resonances (not depicted in FIG. 34B). Deviation in the beam size from the expected diffraction limited size based on COMSOL eigenmode simulations is attributed to imperfect free space optics, including the glass window of the cryostat that the output light from the ski-jump must travel through to be imaged. The ICCD measurements were used at high vacuum to calculate the pixel density, full-fill refresh rate, and beam spot capacity of our device while driving the first X resonance at 40 Vpp and the first or second Y resonance at various voltages.

Because the tip of the cantilever device is the end of a waveguide, the device can be operated at a wide range of wavelengths, as opposed to grating couplers which have a narrow wavelength range. For beam scanning at ambient pressure for the second resonance when inputting visible light from 450 nm to 650 nm, the bandwidth is dictated by the size of the waveguide for which a mode at a given frequency can propagate, which can be designed to carry single mode wavelengths into the near-infrared.

The frequency response at various pressures was characterized by applying an AC voltage while monitoring the y-directional and x-directional positions with a position sensitive photodetector (PSD). Enhancement was measured by comparing the PSD's peak-to-peak amplitude of on-resonant signals to the peak-to-peak amplitude at low frequencies (˜100-400 Hz) (FIG. 34C(i)-34C(v)). The experimental resonances roughly align with simulated resonances, with small deviation likely due to non-ideal parameters of deposited thin films.

For ambient pressure and rough vacuum, the quality factor of a cantilever was measured by taking the Full Width Half Maximum (FWHM) of a Lorentzian fitted peak at each resonance (FIGS. 34C(i)-34C(ii)). At high vacuum, a large increase in the resonant enhancement was observed, along with resonances up to the 150 kHz bandwidth limit of the photodetector (FIG. 34C(iii)). The quality factor was calculated by monitoring the ringdown of a signal after turning off the AC input (FIG. 34C(v)), calculating the decay factor t and the mechanical Q-Factor as Q=πft. Table 1 shows a summary of the resonant frequencies, enhancements, and mechanical quality factors. A peak vacuum resonant enhancement of 1000x (30 dB), with quality factors of over 10,000 was shown.

TABLE 1
Resonant Mode Characterization:

| | Ambient | | | Rough Vacuum | | | High Vacuum | | | High Vacuum, Cryo | | |
|---|---|---|---|---|---|---|---|---|---|---|---|---|
| | Pressure | | | (1.15 Torr) | | | (<0.1 mTorr) | | | (<0.1 mTorr, 6.9K) | | |
| | Freq | Enh | | Freq | Enh | | Freq | Enh | | Freq | Enh | |
| Res. | (kHz) | (dB) | Q | (kHz) | (dB) | Q | (kHz) | (dB) | Q | (kHz) | (dB) | Q |
| 1st | 1.16 | 10 | 5.4 | 1.23 | 15.3 | 24.4 | 1.22 | 30 | 10000* | 1.28 | 18.1 | 2000* |
| Y | | | | | | | | | | | | |
| 2nd | 5.75 | 2.9 | 12.2 | 6.17 | 13 | 101.3 | 6.01 | 23.4 | 6800* | 3.98 | 17.2 | 3000* |
| Y | | | | | | | | | | | | |
| 3rd | 17.98 | 0 | 14.9 | 18.9 | 10.6 | 246.6 | 18.66 | 16.7 | | | | |
| Y | | | | | | | | | | | | |
| 4th | 36.31 | −9.6 | 13.6 | 37.4 | 4.2 | 415.4 | 36.96 | 11.6 | | | | |
| Y | | | | | | | | | | | | |
| 1st | 3.74 | −4.8 | 19.8 | 3.97 | 3.7 | 110.4 | 3.87 | 15.6 | 11000* | 2.72 | 12.9 | 8300* |
| X | | | | | | | | | | | | |
| 2nd | 28.4 | −13.7 | 45.3 | 30 | −4 | 635.2 | 29.33 | −0.4 | | | | |
| X | | | | | | | | | | | | |

*Q-factor measured from signal ringdown instead of Full Width Half Maximum. Res. is shorthand for resonances, Freq is shorthand for resonant frequencies, and Enh is shorthand for enhancement.

### Cryogenic Compatibility

The cryogenic compatibility of the cantilevers was characterized by cooling cantilevers down to 6.9 K. Significant mode curling was observed compared to room temperature. This can be attributed to a differential thermal coefficient of expansion between the various thin film layers, implying that the foot-print of a device designed to operate at cryogenic temperatures could be made significantly smaller, thereby increasing the density of beam steering devices on a chip.

While the devices were curled such that the output was not optimized for collection into the collection objective, mechanical resonances were measured on the ICCD and frequency response was measured using a position sensitive detector, showing >15 dB enhancement of the first and second Y resonance and the first X resonance (FIG. 34C(iv)). Quality factors of >103 via signal ringdown were also measured. Compared to room temperature, resonant frequencies were shifted slightly lower. After returning the device to room temperature, the resonances returned to their original frequencies, indicating stability of the devices under cryogenic cycling conditions.

### Two Dimensional Beam Steering

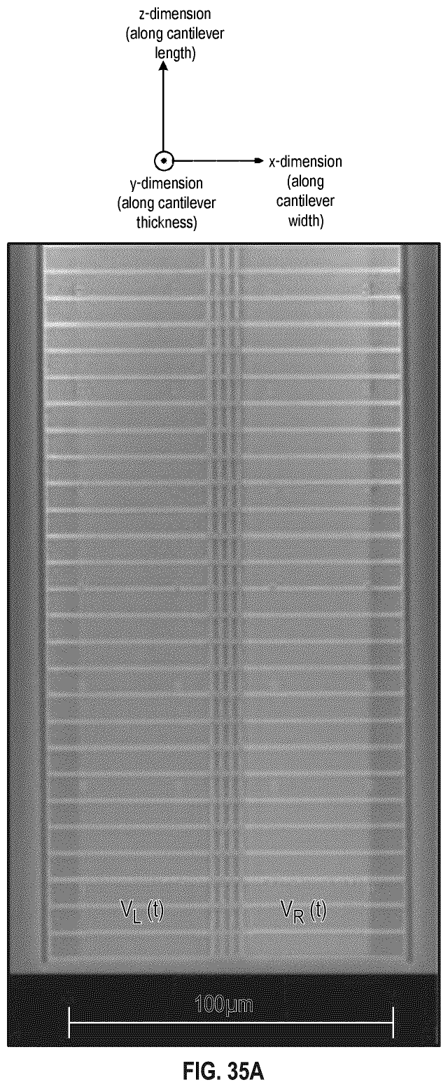

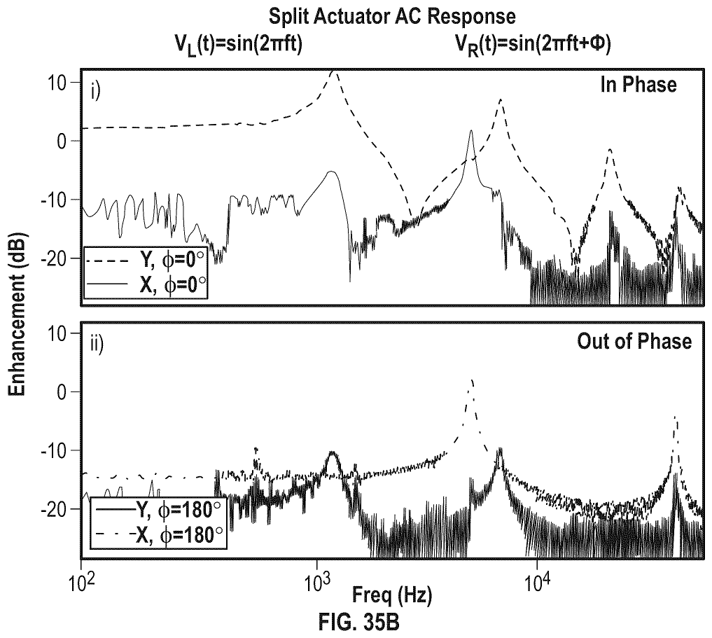

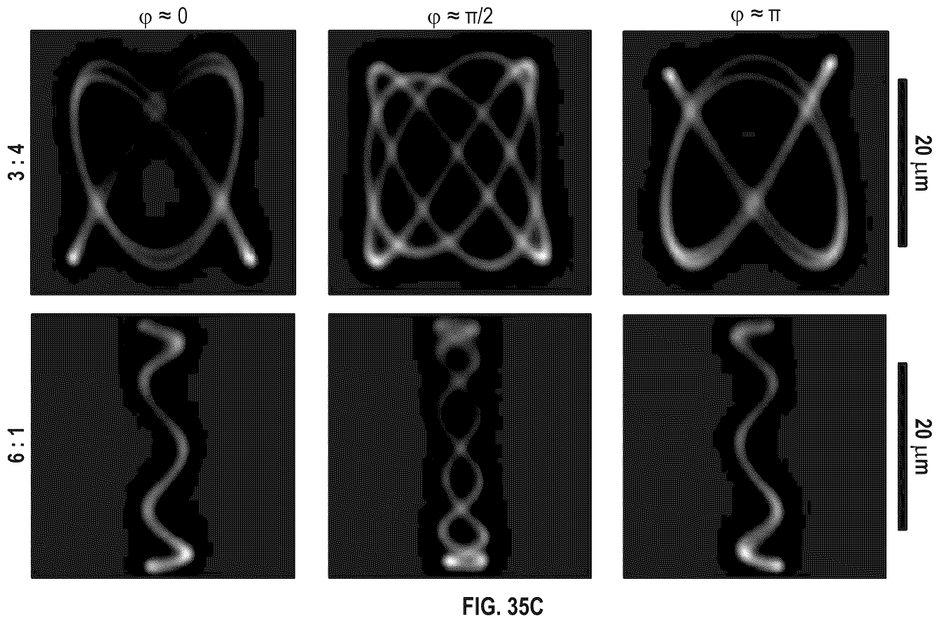

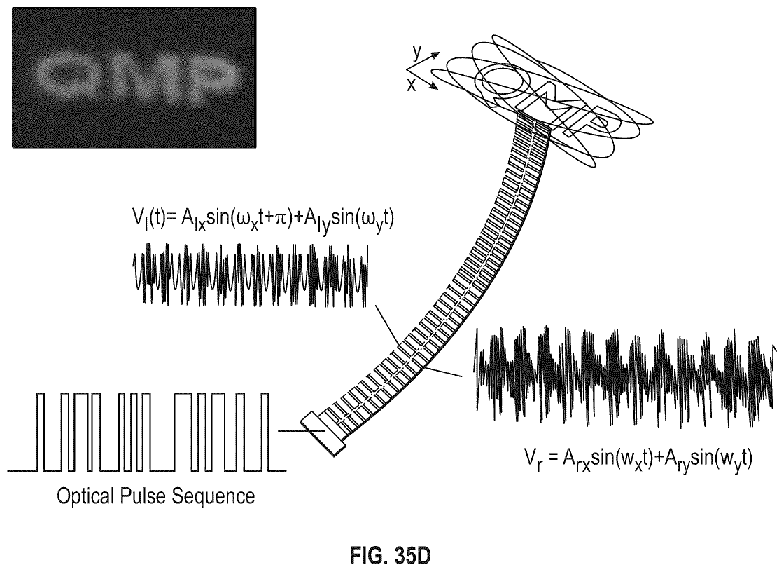

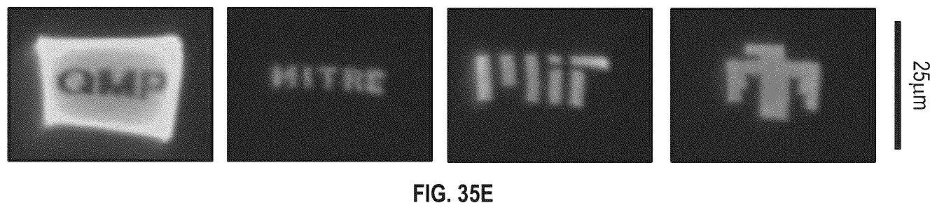

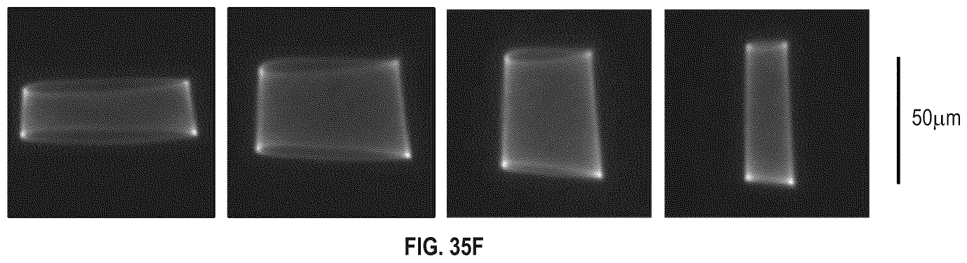

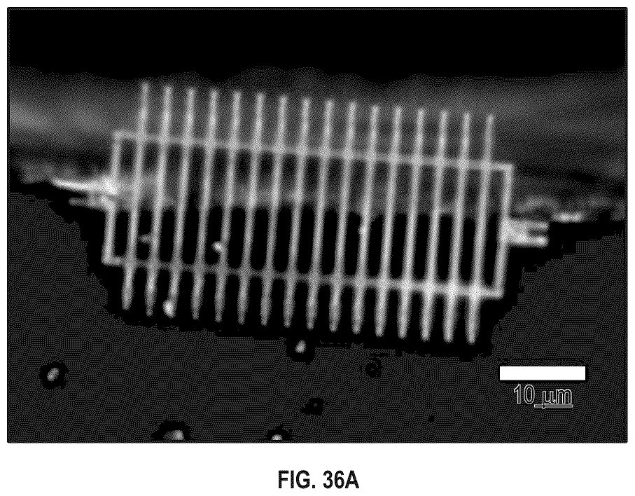

Two-dimensional beam steering was achieved in two ways: (1) by multiplexing two AC signals with variable relative phase and sending them to a single electrode cantilever, with a frequency near a y-dimensional and x-dimensional mechanical resonance, and (2) using split electrode devices where the ground plane is the same, but each half of the device has its own isolated top metal for applying AC voltages via two separate signal pads (FIG. 35A) (e.g., cantilever 2700 or cantilever 3100). Each electrode can be driven at multiple frequencies with different voltage and different relative phase. The y-dimensional and x-dimensional frequency response of the devices were characterized from DC to 50 kHz with dual input signals while measuring the projected beam with a position sensitive quadrant detector (FIG. 35B), indicating that driving out-of-phase signals cancels out the y-dimensional resonance while enhancing the x-dimensional resonance, allowing for cancellation of any cross-coupling (e.g., such as described in reference to FIG. 28A). The result leads to a large space of beam steering Lissajous curves that can be used to beam scan over a two-dimensional grid with varying speeds and density of points.

A cantilever device with dimensions L=950 μm, W=70 μm, WG=300×400 nm, crossbar pitch=4 μm, and 50% etch duty cycle showed passive curling up to 85 degrees. A second order y-dimensional resonance near 6.44 kHz and a x-dimensional resonance near 4.83 kHz were observed, giving a frequency ratio of 4:3. Driving the cantilever with these two frequencies at 20 Vpp and relative phase shifts of 0, π/2, and π generated 3:4 Lissajous curves (FIG. 35C) with a 1.61 kHz refresh rate. A second x-dimensional resonance near 37.2 kHz was also observed, and a 6:1 frequency ratio was generated by setting ω_{y} to 6.2 kHz and ωₓ to 37.2 kHz (FIG. 35C) to project a pattern with a 6.2 kHz refresh rate. Offsetting one of the frequencies caused the beam to sweep across the entire 2D area. Larger ratios generated a larger fill factor across the grid for possible LiDAR and image projection applications. By coupling these large-fill scans with an amplitude modulator to generate optical pulses (FIG. 35D), arbitrary images or direct beam spots to specific locations were projected (FIGS. 35E-35F).

### Modulation of Color Center Emission

The cantilevers allow for creation of a 1×N switch, whereby the cantilever is driven on mechanical resonance across multiple diamond color center emitters as quantum memories to perform an initialization and readout of their quantum state. The cantilever device has a continuous range of outputs within the resonance drive limits with two-dimensional beam steering to control quantum memories as nodes on a grid. As such, the number of channels available scales based on the resolution of the mode exiting the waveguide tip and the range over which the cantilever can be driven within a reasonable voltage range (<100 Vpp).

This capability was demonstrated on a device with dimensions L=950 μm, W=90 μm, WG=300×400 nm, crossbar pitch=4 μm, 75% etch duty cycle. In some embodiments, the device includes two waveguides, but only one waveguide is used for qubit control. The device was wire bonded on a PCB (e.g., printed circuit board) and the optical input is fiber packaged to a grating. A tunable resonant laser around 737 nm was sent through the packaged cantilever and routed in free space to a confocal objective to be incident on a diamond sample in a cryostat below (see experimental setup illustrated in FIG. 36E).

A diamond “quantum microchiplet” (QMC) consisting of 8 waveguides and containing negatively charged silicon monovacancy (SiV-) color centers was placed in a Montana cryostat overhanging an Si substrate vertically (FIG. 36A). Laser light resonant with the SiV-zero phonon line (ZPL) was routed from the end of the cantilever in free space to the tips of individual waveguides from above. As the color centers may ionize to a dark neutral state and over time will cycle into an excited spin state, a broad 532 nm repump green laser was periodically pulsed from the side window of the cryostat onto the entire chiplet to reset the color centers into their bright state.

The diamond chiplet contained an ensemble of SiV centers with a heterogeneous distribution of ZPL frequencies. Towards the end of the range were single SiVs that could be addressed at a given laser excitation frequency. While not driving the output of the cantilever (e.g., not applying a DC or AC voltage to the cantilever), its output was directed to one of the waveguide channels to excite a single emitter, which was verified by second order auto-correlation measurement (FIG. 36B). The cantilever was driven at a mechanical resonance at 3,170 Hz 100 Vpp to repeatably initialize this single emitter and cause the cantilever to move at a rate of 6,340 Hz, with verification by collecting the side band emission into an avalanche photodiode coupled to an IDQ time-tagger for time-resolved measurements of the emitter readout. This shows repeatable and reliable laser pulses incident on the emitter with an extinction ratio of −27.5 dB between laser on and off the emitter (FIG. 36C). Multiple emitters in different waveguide channels can therefore be controlled using a single drive frequency by tuning the resonant laser to a frequency that will excite SiVs in each waveguide channel. The cantilever was driven at the same frequency and voltage and the sideband signal was collected from each emitter onto a high-speed intensified CCD (FIG. 36D), showing the real time counts out of each waveguide channel as the cantilever sweeps over them (FIG. 36D).

Because the chiplet had an ensemble of SiV emitters with randomly distributed ZPL frequencies, single emitters could not be excited in separate waveguide channels at the same time. However, existing methods to tune emitters in separate waveguides to the same resonance, such as strain and capacitive tuning could be used.

To further improve the capabilities of this device, a bulk or on-chip electro-optic modulator such as thin film lithium niobate could be used to generate pulse carving capabilities upstream of the cantilevers to generate optical x pulses incident on each separate color center for initialization and readout of qubit states. This combination of modulators could also improve the extinction ratio further when controlling the qubits.

### Example 17: Using a Frequency-Multiplexed Input and Ring Resonators to Address Multiple Color Centers on a Diamond Waveguide Array

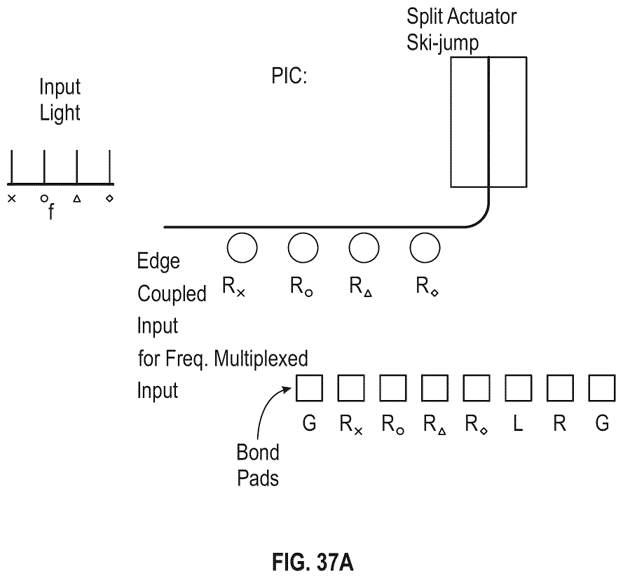

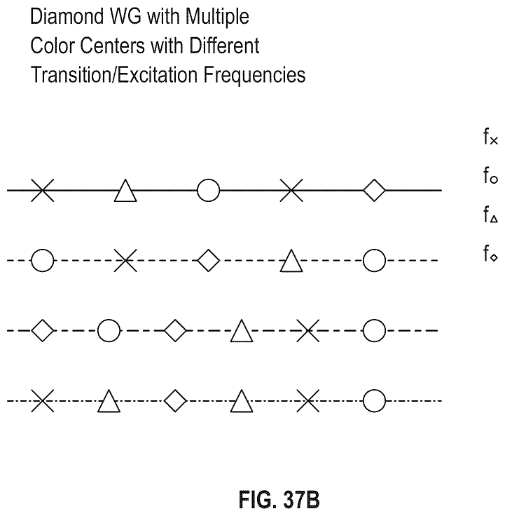

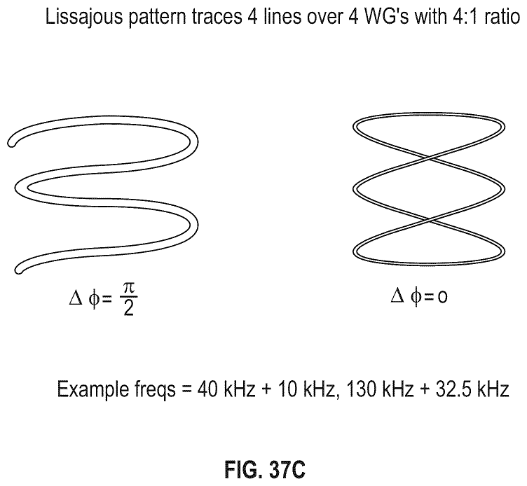

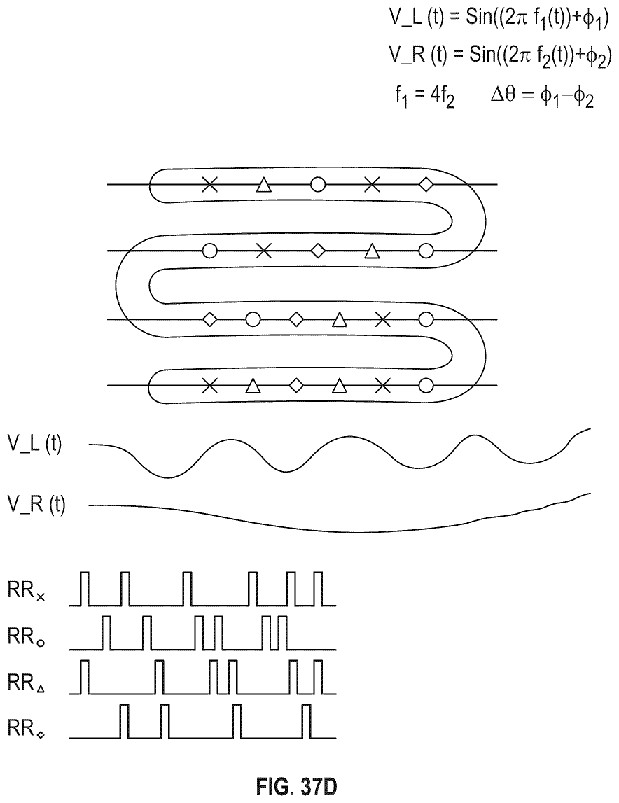

A diamond waveguide array can have multiple waveguides with embedded color centers. FIGS. 37A-37D illustrate controlling a frequency of the output light from one or more waveguides of a cantilever (e.g., such as cantilever 2700 or cantilever 3100) to optically initialize and/or excite color centers with a plurality of optical initialization and/or excitation frequencies (fₓ, fₒ, f_{Δ}, f_{∘}). In some embodiments, a PIC with one or more cantilevers (e.g., such as cantilever 2700 or cantilever 3100) may include an edge coupled optical input for a frequency multiplexed optical signal that comprises the optical initialization and excitation frequencies for the different color centers (FIG. 37A). The PIC may include multiple piezoelectrically actuated ring resonators (FIG. 37A). Each piezoelectrically actuated ring resonator can be tuned with a DC voltage or temperature to one of the optical frequencies to prevent light at that optical frequency from being transmitted from the cantilever. However, a fast piezoelectric pulse can cause that optical signal to transmit from the cantilever (FIG. 37D). Piezoelectric ring actuation can create nanosecond optical pulses. In some embodiments, the one or more cantilevers of the PIC are programmed with a 4:1 y-dimensional vs x-dimensional frequency ratio. This may cause the beam (e.g., output light from the one or more waveguides of the one or more cantilevers) to trace a zig zag or hourglass shape that can be imaged with a spatial light modulator (SLM) to trace along the multiple waveguides (FIG. 37C). Voltage signals may drive the cantilever with repeating sine waves, tracing a 4:1 Lissajous pattern with a high repetition rate (FIG. 37D).

The foregoing description, for the purpose of explanation, has been described with reference to specific embodiments and/or examples. However, the illustrative discussions above are not intended to be exhaustive or to limit the invention to the precise forms disclosed. Many modifications and variations are possible in view of the above teachings. The embodiments were chosen and described in order to best explain the principles of the techniques and their practical applications. Others skilled in the art are thereby enabled to best utilize the techniques and various embodiments with various modifications as are suited to the particular use contemplated.

Although the disclosure and examples have been fully described with reference to the accompanying figures, it is to be noted that various changes and modifications will become apparent to those skilled in the art. Such changes and modifications are to be understood as being included within the scope of the disclosure and examples as defined by the claims. Finally, the entire disclosure of the patents and publications referred to in this application are hereby incorporated herein by reference.

1. A cantilever comprising:
a first dielectric layer, wherein the first dielectric layer has a first intrinsic stress;
a second dielectric layer overlaying the first dielectric layer, wherein the second dielectric layer has a second intrinsic stress that is different than the first intrinsic stress;
a first piezoelectric segment disposed between the first dielectric layer and the second dielectric layer at a first position with respect to a first dimension parallel to the first dielectric layer;
a second piezoelectric segment disposed between the first dielectric layer and the second dielectric layer at a second position with respect to the first dimension; and
one or more waveguides patterned in the second dielectric layer.

2. The cantilever of claim 1, wherein the second dielectric layer comprises a plurality of crossbars oriented at an angle relative to a length of the cantilever to control curvature in a width-wise x-dimension of the cantilever perpendicular to the direction of propagation of light in the one or more waveguides.

3. The cantilever of claim 1, wherein the first dimension is a width-wise x-dimension of the cantilever perpendicular to the direction of propagation of light in the one or more waveguides.

4. The cantilever of claim 3, wherein the first piezoelectric segment is disposed adjacent in the x-dimension to a first side of a waveguide of the one or more waveguides patterned in the second dielectric layer.

5. The cantilever of claim 4, wherein the second piezoelectric segment is disposed adjacent in the x-dimension to a second side, opposite the first side, of the waveguide.

6. The cantilever of claim 3, comprising a third piezoelectric segment disposed between the first dielectric layer and the second dielectric layer,
wherein the first piezoelectric segment is disposed at a first position with respect to a x-dimensional dimension of the cantilever, and
wherein the third piezoelectric segment is disposed at a second position with respect to the x-dimensional dimension of the cantilever.

7. The cantilever of claim 3, wherein:
the first piezoelectric segment is disposed at a first position with respect to a x-dimensional dimension of the cantilever, and
the second piezoelectric segment is disposed at a second position with respect to the x-dimensional dimension of the cantilever.

8. The cantilever of claim 1, wherein the first dimension is a x-dimensional dimension of the cantilever.

9. A system comprising:
the cantilever of claim 1;
a light source configured to direct light into a waveguide of the one or more waveguides of the cantilever; and
one or more voltage sources configured to apply a first voltage to the first piezoelectric segment and a second voltage to the second piezoelectric segment.

10. The system of claim 9, comprising one or more processors configured to control the one or more voltage sources to cause deflection of the cantilever tip in an x-dimension and a y-dimension, wherein the x-dimension is width-wise dimension of the cantilever, the y-dimension is a thickness dimension of the cantilever, and the x-dimension and the y-dimension are perpendicular to one another and are both perpendicular to a positive z direction defined by the direction of propagation of light in the one or more waveguides.

11. The system of claim 10, wherein the one or more processors are configured to control the one or more voltage sources to:
apply the first voltage to drive the first piezoelectric segment at a first frequency and the second voltage to drive the second piezoelectric segment at the first frequency to induce oscillation of the cantilever at a x-dimensional resonance frequency.

12. The system of claim 10, wherein the one or more processors are configured to control the one or more voltage sources to modulate an amplitude of the first and/or second voltage in accordance with a y-dimensional cancellation amplitude of the cantilever.

13. The system of claim 10, wherein the one or more processors are configured to control the one or more voltage sources to modulate a relative phase of the first and second voltages with respect to one another in accordance with a y-dimensional cancellation phase of the cantilever.

14. The system of claim 10, wherein the one or more processors are configured to control the one or more voltage sources to:
detect a position of output light output from the waveguide in an imaging plane over time as the cantilever is driven at the x-dimensional resonance frequency; and
modulate the first and/or second voltage in accordance with the monitored position of the output light in the imaging plane.

15. The system of claim 10, wherein the one or more processors are configured to control the one or more voltage sources to:
apply the first voltage to drive the first piezoelectric segment at the first frequency and the second voltage to drive the second piezoelectric segment at the first frequency to induce oscillation of the cantilever at a y-dimensional resonance frequency.

16. The system of claim 10, wherein the one or more processors are configured to control the one or more voltage sources to modulate the amplitude of the first and/or second voltage in accordance with a x-dimensional cancellation amplitude of the cantilever.

17. The system of claim 10, wherein the one or more processors are configured to control the one or more voltage sources to modulate the relative phase of the first and second voltages with respect to one another in accordance with a x-dimensional cancellation phase of the cantilever.

18. The system of claim 10, wherein the one or more processors are configured to control the one or more voltage sources to:
detect a position of output light output from the waveguide in an imaging plane over time as the cantilever is driven at the y-dimensional resonance frequency; and
modulate the first and/or second voltage in accordance with the monitored position of the output light in the imaging plane.

19. The system of claim 10, wherein the one or more processors are configured to control the one or more voltage sources to:
apply the first voltage to drive the first piezoelectric segment and the second voltage to drive the second piezoelectric segment to induce oscillation of the cantilever in accordance with a Lissajous pattern, wherein the Lissajous pattern is generated in accordance with a ratio of the y-dimensional resonance frequency of the cantilever and the x-dimensional resonance frequency of the cantilever.

20. The system of claim 10, wherein the one or more processors are configured to control the light source to apply pulsed light to the waveguide as the cantilever oscillates in accordance with the Lissajous pattern.
